(19) United States
(12) Patent Application Publication
(10) Pub. No.: US 2025/0287613 A1
(43) Pub. Date: Sep. 11, 2025

(54) MEMORY DEVICE

(71) Applicant: SAMSUNG ELECTRONICS CO., LTD., Suwon-si (KR)

(72) Inventor: Eunji KIM, Suwon-si (KR)

(73) Assignee: SAMSUNG ELECTRONICS CO., LTD., Suwon-si (KR)

(21) Appl. No.: 19/016,828

(22) Filed: Jan. 10, 2025

(30) Foreign Application Priority Data
Mar. 7, 2024 (KR) 10-2024-0032839

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08145; H01L 2225/06541; H01L 2924/1431; H01L 2924/14511

(57) ABSTRACT

A memory device may include a first cell array chip including a first memory cell array, a first peripheral circuit chip including a first page buffer circuit electrically connected to the first memory cell array, an input/output (I/O) chip including a first pad circuit, a second pad circuit, a first I/O circuit electrically connected to the first pad circuit, and a second I/O circuit electrically connected to the second pad circuit. The memory device may further include a second cell array chip including a second memory cell array; and a second peripheral circuit chip including a second page buffer circuit electrically connected to the second memory cell array.

### CROSS-REFERENCE TO RELATED APPLICATION

This application is based on and claims priority under 35 U.S.C. § 119 to Korean Patent Application No. 10-2024-0032839, filed on Mar. 7, 2024, in the Korean Intellectual Property Office, the disclosure of which is incorporated by reference herein in its entirety.

### BACKGROUND

### 1. Field

Embodiments of the present disclosure relate to a memory device, and more particularly, to a memory device having a structure in which a plurality of chips are stacked in a vertical direction.

### 1. Brief Description of Related Art

Recently, with the growing tendency toward small-sized and highly efficient devices in the semiconductor industry, downscaling semiconductor chips is emerging as an important task. Against this background, there is an increasing demand for structural and functional improvements in memory semiconductor devices.

A vertical memory structure has become one of the important solutions to meet the demand. That is, in the vertical memory structure, as the number of stages in a memory cell array increases, an area occupied by the memory cell array, from among components included in a memory device, may comparatively reduce. However, due to technical and physical limitations, an extent to which an area of a peripheral circuit is reduced may not reach an extent to which an area of the memory cell array is reduced.

In addition, as memory cell array chips are stacked, a distance between the memory cell array and the peripheral circuit may increase, which may increase load applied to the peripheral circuit. As a result, the increase in load may deteriorate the performance of the memory device.

### SUMMARY

Embodiments of the present disclosure provide a memory device, which has a structure capable of improving the net die of semiconductor chips included in the memory device and may minimize load applied to the memory device when the memory device performs input/output (I/O) operations.

The technical aspects of embodiments of the present disclosure are not limited to those described above; other aspects may become apparent to those of ordinary skill in the art based on the following description.

According to embodiments of the present disclosure, a memory device may be provided and include: a first cell array chip including a first memory cell array; a first peripheral circuit chip including a first page buffer circuit electrically connected to the first memory cell array; an input/output chip including a first pad circuit, a second pad circuit, a first input/output circuit electrically connected to the first pad circuit, and a second input/output circuit electrically connected to the second pad circuit; a second cell array chip including a second memory cell array; and a second peripheral circuit chip including a second page buffer circuit electrically connected to the second memory cell array.

According to embodiments of the present disclosure, a memory device may be provided and include: a first cell array chip including a first memory cell array; a first peripheral circuit chip including a first page buffer circuit electrically connected to the first memory cell array; a second cell array chip including a second memory cell array; and a second peripheral circuit chip including a second page buffer circuit, a first pad circuit, a second pad circuit, a first input/output circuit electrically connected to the first pad circuit, and a second input/output circuit electrically connected to the second pad circuit, wherein the second page buffer circuit is electrically connected to the second memory cell array and formed on one surface of the second peripheral circuit chip, and wherein the first pad circuit, the second pad circuit, the first input/output circuit, and the second input/output circuit are formed on another surface of the second peripheral circuit chip.

According to embodiments of the present disclosure, a memory device may be provided and include: a first cell array chip including a first memory cell array; a first peripheral circuit chip including a first page buffer circuit electrically connected to the first memory cell array; an input/output chip including a first pad circuit, a second pad circuit, a first input/output circuit electrically connected to the first pad circuit, and a second input/output circuit electrically connected to the second pad circuit; a second cell array chip including a second memory cell array; a second peripheral circuit chip including a second page buffer circuit electrically connected to the second memory cell array; a third cell array chip including a third memory cell array; and a third peripheral circuit chip including a third page buffer circuit electrically connected to the third memory cell array.

### BRIEF DESCRIPTION OF DRAWINGS

Embodiments will be more clearly understood from the following detailed description taken in conjunction with the accompanying drawings in which:

FIG. 1 is a block diagram of a storage device according to embodiments;

FIG. 2 is a block diagram of a memory device according to embodiments;

FIG. 3 is a view illustrating a structure of the memory device of FIG. 1, according to embodiments;

FIGS. 4 and 5 are views illustrating memory devices according to embodiments;

FIGS. 6 and 7 are views illustrating memory devices according to embodiments;

FIG. 8 is a view illustrating a memory device according to embodiments;

FIGS. 9A and 9B are views illustrating an operating method of a memory device according to embodiments;

FIGS. 10A and 10B are views illustrating an operating method of a memory device according to embodiments;

FIGS. 11A and 11B are views illustrating an operating method of a memory device according to embodiments;

FIGS. 12A and 12B are views illustrating an operating method of a memory device according to embodiments;

FIGS. 13 to 16 are views respectively illustrating memory devices according to embodiments;

FIGS. 17 to 20 are views respectively illustrating memory devices according to embodiments;

FIG. 21 is a view illustrating a memory device according to embodiments;

FIG. 22 is a view illustrating a memory device according to embodiments;

FIG. 23 is a view illustrating a memory device according to embodiments;

FIG. 23 is a view illustrating a memory device according to embodiments;

FIG. 25 is a view illustrating a memory device according to embodiments; and

FIG. 26 is a block diagram of an example of applying a memory device according to embodiments to a solid-state drive (SSD) system.

### DETAILED DESCRIPTION

Hereinafter, non-limiting example embodiments of the present disclosure will be described in detail with reference to the accompanying drawings. The same reference numerals are used to denote the same elements in the drawings, and repeated descriptions thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

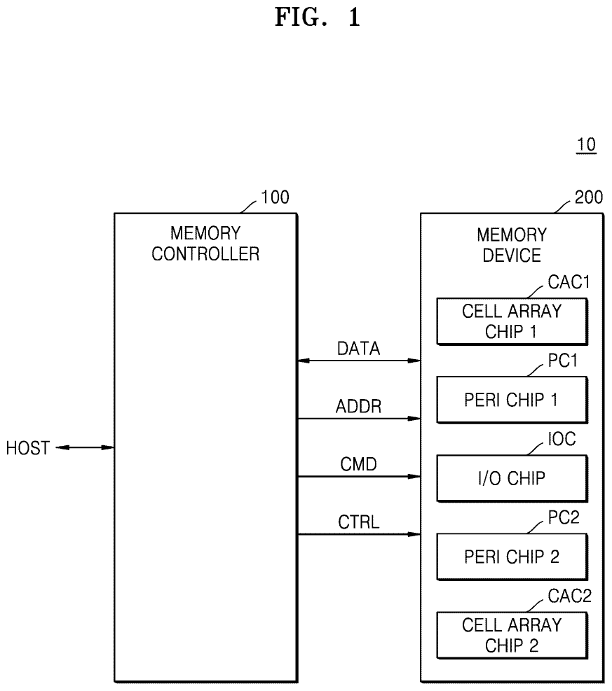

FIG. 1 is a block diagram of a storage device 10 according to embodiments.

Referring to FIG. 1, the storage device 10 may include storage mediums configured to store data in response to a request from a host. For example, the storage device 10 may include at least one from among a solid-state drive (SSD), an embedded memory, and a removable external memory. When the storage device 10 is the SSD, the storage device 10 may be a device that conforms to a non-volatile memory express (NVMe) standard.

When the storage device 10 is the embedded memory or the external memory, the storage device 10 may be a device that conforms to the standard of a universal flash storage (UFS) or an embedded multi-media card (eMMC). Each of the host and the storage device 10 may generate and transmit packets that conform to an adopted standard protocol. In an embodiment, the storage device 10 may be an embedded memory that is embedded in the storage device 10. For example, the storage device 10 may include an eMMC or an embedded UFS memory device. In an embodiment, the storage device 10 may be external memory that is detachably attached to another system. For example, the storage device 10 may include a UFS memory card, a compact flash (CF), a secure digital (SD), a micro-SD, a mini-SD, an extreme Digital (xD), or a memory stick.

Referring to FIG. 1, the storage device 10 may include a memory controller 100 and a memory device 200.

The memory controller 100 may control read, write, and erase operations on the memory device 200 by providing an address ADDR, a command CMD, and a control signal CTRL to the memory device 200. In this case, when the memory device 200 performs read and write operations, data DATA may be transmitted and received between the memory controller 100 and the memory device 200.

In an embodiment, the memory controller 100 may control the memory device 200 to read data stored in the memory device 200 in response to a read request from a host HOST or write data to the memory device 200 in response to a write request from the host HOST. In an embodiment, the storage device 10 may perform operations, such as wear leveling management, bad block management, and garbage collection.

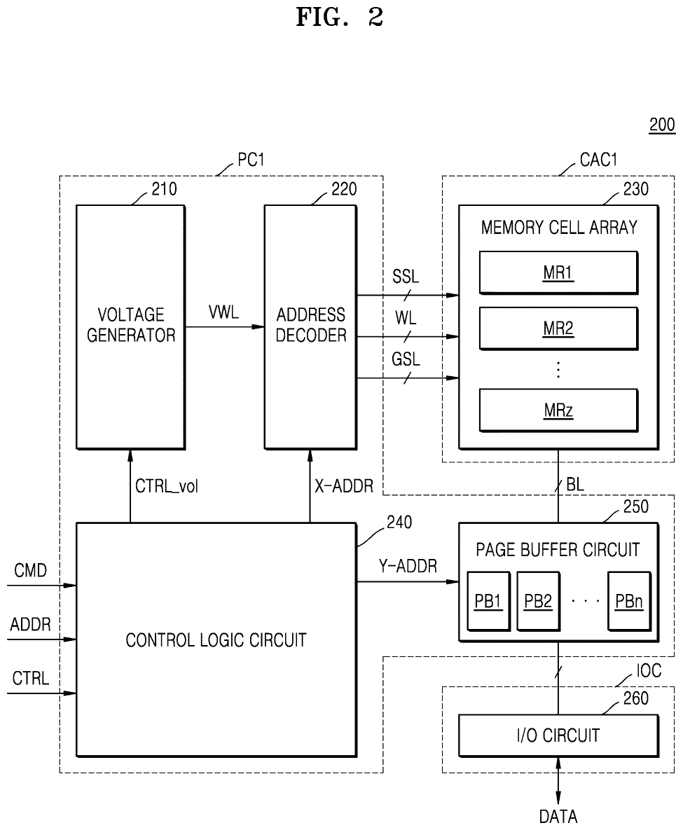

The memory device 200 may include a first cell array chip CAC1, a first peripheral circuit chip PC1, an input/output (I/O) chip IOC, a second peripheral circuit chip PC2, and a second cell array chip CAC2. The first cell array chip CAC1, the first peripheral circuit chip PC1, the I/O chip IOC, the second peripheral circuit chip PC2, and the second cell array chip CAC2 may each be a semiconductor chip that is formed on a separate wafer and then diced. Each of the first cell array chip CAC1 and the second cell array chip CAC2 may include a memory cell array. The first peripheral circuit chip PC1 may include circuits to control the memory cell array included in the first cell array chip CAC1. The second peripheral circuit chip PC2 may include circuits to control the memory cell array included in the second cell array chip CAC2. The I/O chip IOC may include a pad circuit connected to a bonding pad and an I/O circuit to transmit and receive data to and from the first peripheral circuit chip PC1 and the second peripheral circuit chip PC2. Component blocks included in each of the first cell array chip CAC1, the first peripheral circuit chip PC1, the I/O chip IOC, the second peripheral circuit chip PC2, and the second cell array chip CAC2 are described below with reference to FIG. 2.

FIG. 2 is a block diagram of a memory device 200 according to embodiments. FIG. 2 may be described with reference to FIG. 1, and repeated descriptions may be omitted. Although only a first cell array chip CAC1, a first peripheral circuit chip PC1, and an I/O chip IOC are illustrated in FIG. 2 for brevity, the memory device 200 of FIG. 2 may further include a second cell array chip CAC2 and a second peripheral circuit chip PC2. In this case, the second cell array chip CAC2 may have a similar configuration to the configuration of the first cell array chip CAC1, and the second peripheral circuit chip PC2 may have a similar configuration to the configuration of the first peripheral circuit chip PC1.

Referring to FIG. 2, the memory device 200 may include the first cell array chip CAC1, the first peripheral circuit chip PC1, and the I/O chip IOC.

The first peripheral circuit chip PC1 may include a voltage generator 210, an address decoder 220, a control logic circuit 240, and a page buffer circuit 250. The first cell array chip CAC1 may include a memory cell array 230. The I/O chip PC1 may include an I/O circuit 260.

The voltage generator 210 may generate various kinds of voltages for performing read, write, and erase operations on the memory cell array 230, based on a voltage control signal CTRL_Vol. Specifically, the voltage generator 210 may generate a word line voltage VWL, for example, a program voltage, a read voltage, a pass voltage, erase verification voltage, or a program verification voltage. Also, the voltage generator 210 may generate a string selection line voltage or a ground selection line voltage, based on the voltage control signal CTRL_Vol. In addition, the voltage generator 210 may generate an erase voltage to be provided to the memory cell array 230.

The address decoder 220 may select one of a plurality of memory regions MR1 to MRz (z is a natural number of 1 or more) of the memory cell array 230, one of word lines WL of the selected memory region, and select one of a plurality of string selection lines SSL.

The memory cell array 230 may be connected to the word lines WL, the string selection lines SSL, ground selection lines GSL, and bit lines BL. The memory cell array 230 may be connected to the address decoder 220 through the word lines WL, the string selection lines SSL, and the ground selection lines GSL and be connected to the page buffer circuit 250 through the bit lines BL. The memory cell array 230 may include the plurality of memory regions MR1 to MRz.

Each of the plurality of memory regions MR1 to MRz may include a plurality of memory cells and a plurality of selection transistors. The memory cells may be connected to the word lines WL, and the selection transistors may be connected to the string selection lines SSL or the ground selection lines GSL. Each of the plurality of memory regions MR1 to MRz may include a plurality of memory pages A memory page may correspond to a program unit of data or a read unit of data. As used herein, a memory region may refer to a group of a plurality of memory cells. Alternatively, each memory region may correspond to a memory block.

In an embodiment, the memory cell array 230 may include a three-dimensional (3D) a memory cell array, which includes a plurality of NAND strings. Each of the NAND strings may include memory cells respectively connected to word lines WL that are vertically stacked on a substrate. However, embodiments of the present disclosure are not limited thereto. In some embodiments, the memory cell array 230 may include a two-dimensional (2D) memory cell array, which includes a plurality of NAND strings arranged in a row direction and a column direction.

The control logic circuit 240 may output various control signals for performing read, write, and erase operations on the memory cell array 230, based on a command CMD, an address ADDR, and a control signal CTRL. The control logic circuit 240 may provide a row address X-ADDR to the address decoder 220, provide a column address Y-ADDR to the page buffer circuit 250, and provide a voltage control signal CTRL_Vol to the voltage generator 210.

The page buffer circuit 250 may include a plurality of page buffers PB1 to PBn (n is a natural number of 1 or more). The plurality of page buffers PB1 to PBn may respectively correspond to the plurality of memory regions MR1 to MRz. The page buffer circuit 250 may operate as a write driver or a sense amplifier according to an operation mode. In a read operation, the page buffer circuit 250 may sense a bit line BL of a selected memory cell via the control of the control logic circuit 240. Sensed data may be stored in latches included in the page buffer circuit 250. The page buffer circuit 250 may dump the data stored in the latches to the I/O circuit 260 via the control of the control logic circuit 240.

The I/O circuit 260 may temporarily store data DATA provided from the outside of the memory device 200. The I/O circuit 260 may temporarily store read data of the memory device 200 and output data to the outside at a designated point in time. In addition, the I/O circuit 260 may temporarily store write data DATA provided from the outside and provide the data DATA to the page buffer circuit 250 at a designated point in time.

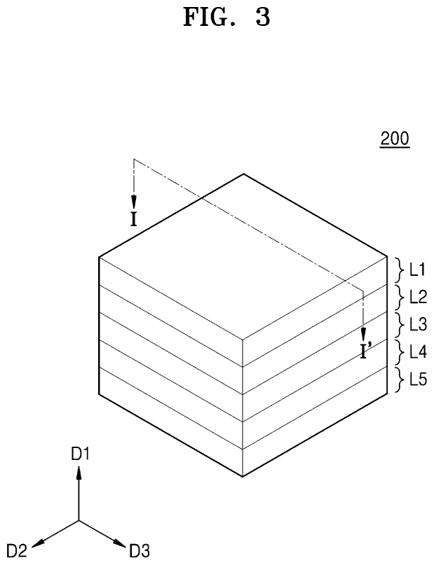

FIG. 3 is a view illustrating a structure of the memory device 200 of FIG. 1, according to embodiments. FIG. 3 may be described with reference to FIGS. 1 and 2, and repeated descriptions may be omitted.

FIG. 3 illustrates one example of structures of the memory device 200 of FIG. 1. Referring to FIG. 3, the memory device 200 may include first to fifth semiconductor layers L1 to L5. The second semiconductor layer L2 may be under the first semiconductor layer L1 in a vertical direction (i.e., a first direction D1). The third semiconductor layer L3 may be under the second semiconductor layer L2 in the first direction D1. The fourth semiconductor layer L4 may be under the third semiconductor layer L3 in the first direction D1. The fifth semiconductor layer L5 may be under the fourth semiconductor layer L4 in the first direction D1.

As used herein, the vertical direction may be defined as the first direction D1, a second direction D2 may be defined as a direction perpendicular to the first direction D1, and a third direction D3 may be defined as a direction perpendicular to the first direction D1 and the second direction D2. Also, the second direction D2 may also be referred to as a first lateral direction, and the third direction D3 may also be referred to as a second lateral direction.

In an embodiment, the memory device 200 may have a symmetrical structure about the third semiconductor layer L3. The first cell array chip CAC1 of FIG. 1 may be formed in the first semiconductor layer L1. The first peripheral circuit chip PC1 of FIG. 1 may be formed in the second semiconductor layer L2. The I/O chip IOC of FIG. 1 may be formed in the third semiconductor layer L3. The second cell array chip CAC2 of FIG. 1 may be formed in the fourth semiconductor layer L4. The second peripheral circuit chip PC2 of FIG. 1 may be formed in the fifth semiconductor layer L5.

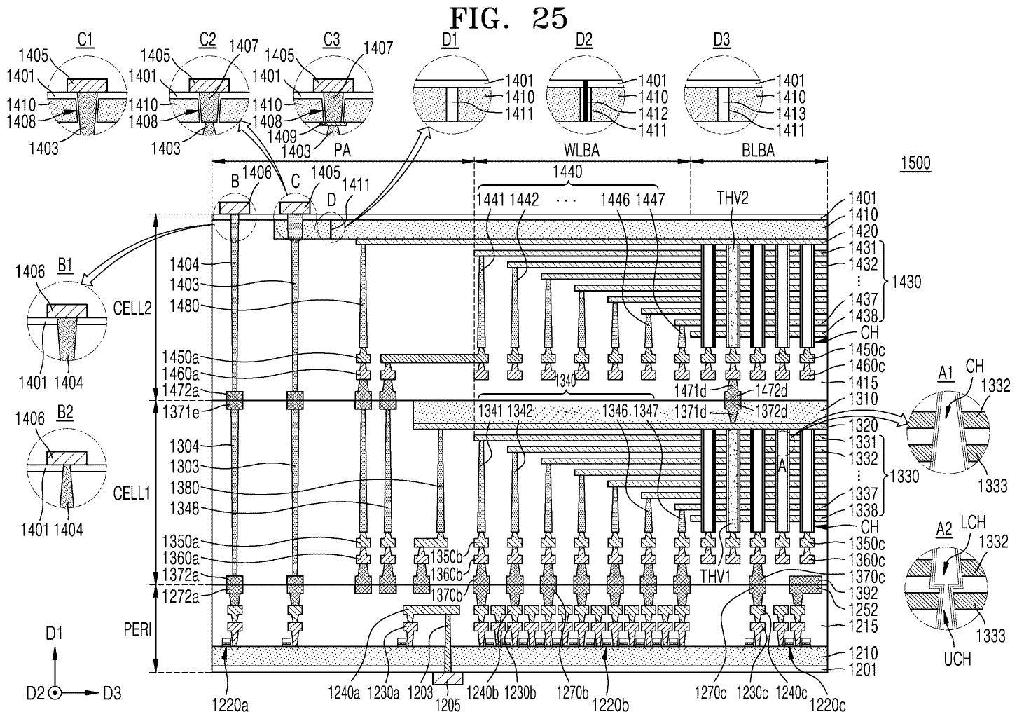

The memory device 200 may include a chip-to-chip (C2C) structure. Here, the C2C structure may refer to a structure in which at least one upper chip including a cell region (e.g., a first cell region CELL1; refer to FIG. 25) and a lower chip including a peripheral circuit region PERI (refer to FIG. 25) are separately manufactured and connected to each other by using a bonding technique.

In an embodiment, the first cell array chip CAC1 and the first peripheral circuit chip PC1 may be connected to each other by using a bonding technique to have a C2C structure. In addition, the second cell array chip CAC2 and the second peripheral circuit chip PC2 may be connected to each other by using a bonding technique to have a C2C structure. A detailed description of the C2C structure is provided below with reference to FIG. 25.

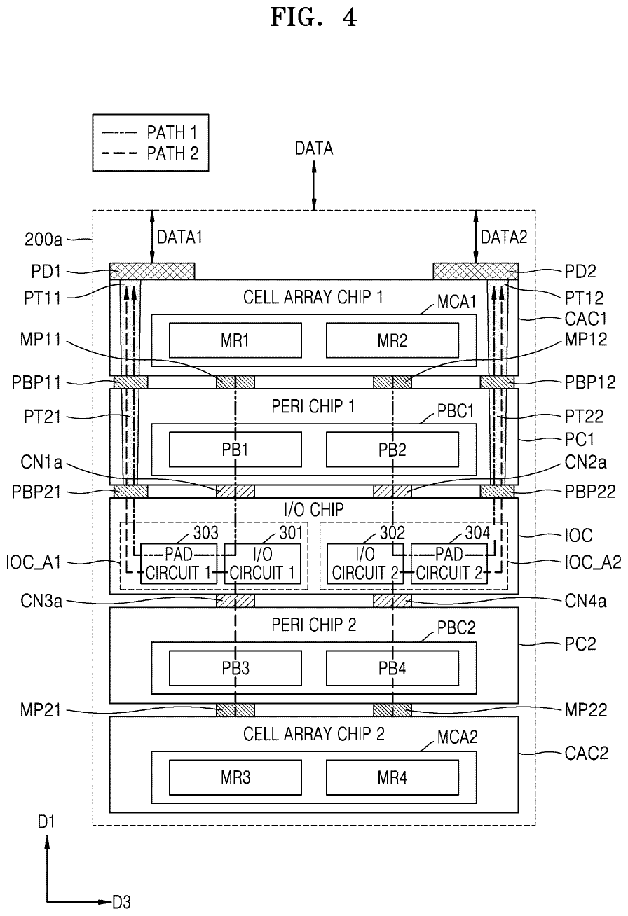

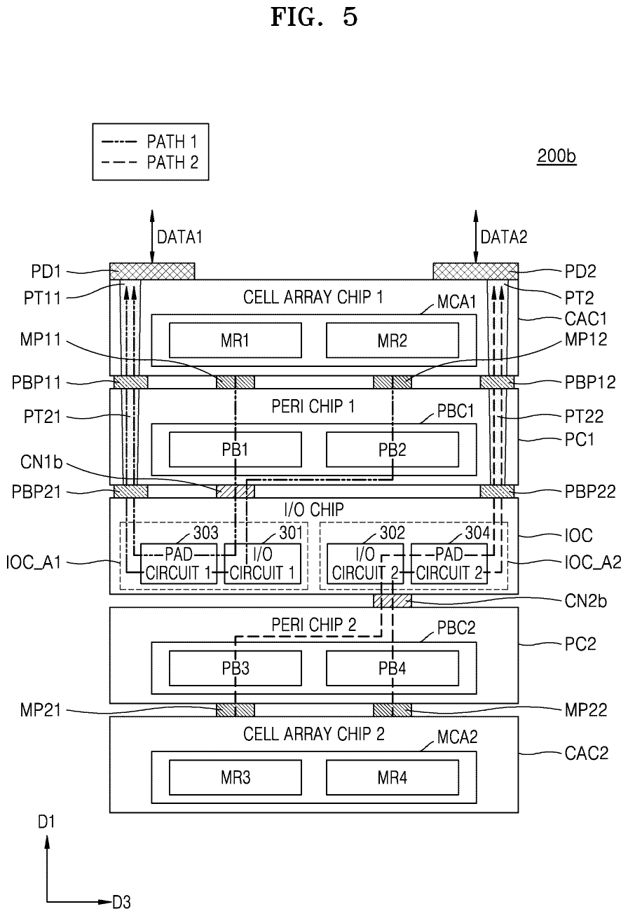

FIGS. 4 and 5 are views illustrating a memory device 200a and a memory device 200b according to embodiments. Specifically, each of FIGS. 4 and 5 corresponds to a cross-section of the memory device 200, which is taken along line I-I′ of FIG. 3. FIGS. 4 and 5 may be described with reference to FIGS. 1 to 3, and repeated descriptions may be omitted.

Referring to FIG. 4, the memory device 200a may include a first cell array chip CAC1, a first peripheral circuit chip PC1, an I/O chip IOC, a second peripheral circuit chip PC2, a second cell array chip CAC2, a first bonding pad PD1, a second bonding pad PD2, contact plugs PT11, PT12, PT21, and PT22, contact bonding pads PBP11, PBP12, PBP21, and PBP22, metal patterns MP11, MP12, MP21, and MP22, and first to fourth connection units CN1a to CN4a. Also, the first bonding pad PD1 and the second bonding pad PD2 may be located on the first cell array chip CAC1. The memory device 200a may communicate with the memory controller 100 (refer to FIG. 1) through the first bonding pad PD1 and the second bonding pad PD2. As used herein, a contact bonding pad may refer to a conductive pad located for electrical connection between a contact plug and another component. In this case, the other component electrically connected to the contact plug may be, for example, another contact plug or another semiconductor chip. The first peripheral circuit chip PC1 may be electrically connected to the first cell array chip CAC1 through the metal patterns MP11 and MP12 by using a bonding technique. The first peripheral circuit chip PC1 may be electrically connected to the I/O chip IOC through the first connection unit CN1a and the second connection unit CN2a. The second peripheral circuit chip PC2 may be electrically connected to the I/O chip IOC through the third connection unit CN3a and the fourth connection unit CN4a. The second peripheral circuit chip PC2 may be electrically connected to the second cell array chip CAC2 through the metal patterns MP21 and MP22 by using a bonding technique.

The first cell array chip CAC1 may include a first memory cell array MCA1. The first memory cell array MCA1 may include a first memory region MR1 and a second memory region MR2. The first memory cell array MCA1 is illustrated as including two memory regions in a descriptive sense only and not for purposes of limitation. That is, the first memory cell array MCA may include more than two memory regions.

The first peripheral circuit chip PC1 may include a first page buffer circuit PBC1. The first page buffer circuit PBC1 may include a first page buffer PB1 and a second page buffer PB2. The first page buffer circuit PBC1 is illustrated as including two page buffers in a descriptive sense only and not for purposes of limitation. That is, the first page buffer circuit PBC1 may include more than two page buffers.

The second cell array chip CAC2 may include a second memory cell array MCA2. The second memory cell array MCA2 may include a third memory region MR3 and a fourth memory region MR4. The second memory cell array MCA2 is illustrated as including two memory regions in a descriptive sense only and not for purposes of limitation. That is, the second memory cell array MCA2 may include more than two memory regions.

The second peripheral circuit chip PC2 may include a second page buffer circuit PBC2. The second page buffer circuit PBC2 may include a third page buffer PB3 and a fourth page buffer PB4. The second page buffer circuit PBC2 is illustrated as including two page buffers in a descriptive sense only and not for purposes of limitation. That is, the second page buffer circuit PBC2 may include more than two page buffers.

The I/O chip IOC may include a first I/O circuit 301, a second I/O circuit 302, a first pad circuit 303, and a second pad circuit 304. Each of the first I/O circuit 301 and the second I/O circuit 302 may correspond to the I/O circuit 260 of FIG. 2. The first I/O circuit 301 may be apart from the second I/O circuit 302 in the third direction D3. The first pad circuit 303 may be closer to the first I/O circuit 301 than the second I/O circuit 302. The second pad circuit 304 may be closer to the second I/O circuit 302 than the first I/O circuit 301. The first memory region MR1, the first page buffer PB1, the third page buffer PB3, and the third memory region MR3 may be closer to the first I/O circuit 301 than the second I/O circuit 302. The second memory region MR2, the second page buffer PB2, the fourth page buffer PB4, and the fourth memory region MR4 may be closer to the second I/O circuit 302 than the first I/O circuit 301.

The I/O chip IOC may be divided into a first I/O unit IOC_A1 and a second I/O unit IOC_A2. As used herein, the first I/O unit IOC_A1 may refer to a region including the first I/O circuit 301 and the first pad circuit 303. The second I/O unit IOC_A2 may refer to a region including the second I/O circuit 302 and the second pad circuit 304.

The first pad circuit 303 may be a circuit configured to electrically connect the first I/O circuit 301 to the first bonding pad PD1. The second pad circuit 304 may be a circuit configured to electrically connect the second I/O circuit 302 to the second bonding pad PD2. The first bonding pad PD1 may be electrically connected to the first pad circuit 303 through the contact plug PT11 and the contact plug PT21. The contact plug PT11 and the contact plug PT12 may pass through the first cell array chip CAC1. The contact plug PT21 and the contact plug PT22 may pass through the first peripheral circuit chip PC1. The contact plug PT11 may be electrically connected to the contact plug PT21 through the contact bonding pad PBP11. The contact plug PT21 may be electrically connected to the I/O chip IOC through the contact bonding pad PBP21. The contact plug PT12 may be electrically connected to the contact plug PT22 through the contact bonding pad PBP12. The contact plug PT22 may be electrically connected to the I/O chip IOC through the contact bonding pad PBP22. In an embodiment, the contact bonding pads PBP11 and PBP12 may be between the first cell array chip CAC1 and the first peripheral circuit chip PC1. In an embodiment, the contact bonding pads PBP21 and PBP22 may be between the first peripheral circuit chip PC1 and the I/O chip IOC.

According to embodiments, a first contact passing through the first peripheral circuit chip PC1 and the first cell array chip CAC1 may be provided. For example, the first contact may include the contact plug PT11 and the contact plug PT21. According to embodiments, a second contact passing through the first peripheral circuit chip PC1 and the first cell array chip CAC1 may be provided. The second contact may include the contact plug PT12 and the contact plug PT21.

The memory device 200a may perform an I/O operation (e.g., a write operation or a read operation) related to data DATA, by using an I/O circuit that is close to each memory region.

In an embodiment, the memory device 200a may write data DATA to the first cell array chip CAC1 or read the data DATA from the first cell array chip CAC1 through a first path PATH1. The first path PATH1 may refer to a path passing through the first cell array chip CAC1, the first peripheral circuit chip PC1, and the I/O chip IOC. In this case, the memory device 200a may process the input and output of data related to the first memory region MR1 by using the first page buffer PB1 and the first I/O circuit 301, and process the input and output of data related to the second memory region MR2 by using the second page buffer PB2 and the second I/O circuit 302.

In an embodiment, the memory device 200a may write data DATA to the second cell array chip CAC2 or read the data DATA from the second cell array chip CAC2 through a second path PATH2. The second path PATH2 may refer to a path passing through the second cell array chip CAC2, the second peripheral circuit chip PC2, and the I/O chip IOC. In this case, the memory device 200a may process the input and output of data related to the third memory region MR3 by using the third page buffer PB3 and the first I/O circuit 301, and process the input and output of data related to the fourth memory region MR4 by using the fourth page buffer PB4 and the second I/O circuit 302.

The memory device 200a may perform 1-channel communication with the memory controller 100. That is, the memory device 200a may transmit and receive data DATA to and from the memory controller 100 through the first bonding pad PD1 and the second bonding pad PD2 in response to a first command received from the memory controller 100. The data DATA may include first data DATA1 and second data DATA2. The first data DATA1 may correspond to lower bits, from among bits that constitute the data DATA, and the second data DATA2 may correspond to upper bits, from among the bits that constitute the data DATA. However, embodiments of the present disclosure are not limited thereto, and the first data DATA1 may correspond to the upper bits, from among bits that constitute the data DATA, and the second data DATA2 may correspond to the lower bits, from among the bits that constitute the data DATA.

In an embodiment, a size unit of the data DATA that are input and output between the memory device 200a and the memory controller 100 may be 16 bits. In this case, the memory device 200a may operate as a wide I/O interface. The first data DATA1 may correspond to lower 8-bit data of the data DATA, and the second data DATA2 may correspond to upper 8-bit data of the data DATA.

In an embodiment, a size unit of the data DATA that are input and output between the memory device 200a and the memory controller 100 may be 8 bits. In this case, the first data DATA1 may correspond to lower 4-bit data of the data DATA, and the second data DATA2 may correspond to upper 4-bit data of the data DATA.

Referring to FIG. 5, the memory device 200b may include components corresponding to the memory device 200a of FIG. 4. Hereinafter, repeated descriptions may be omitted, and the description below focuses on differences between the memory device 200b of FIG. 5 and the memory device 200a of FIG. 4.

However, unlike in the memory device 200a of FIG. 4, a first peripheral circuit chip PC1 of the memory device 200b of FIG. 5 may be electrically connected to a first I/O unit IO_A1 through a first connection unit CN1b. Similarly, the second peripheral circuit chip PC2 of the memory device 200b of FIG. 5 may be electrically connected to the second I/O unit IO_A2 through a second connection unit CN2b.

The memory device 200b may process an I/O operation related to a first cell array chip CAC1 by using a first I/O circuit 301 and perform an I/O operation related to a second cell array chip CAC2 by using the second I/O circuit 302.

In an embodiment, the memory device 200b may write first data DATA1 to the first cell array chip CAC1 or read the first data DATA1 from the first cell array chip CAC1 through the first path PATH1. The first path PATH1 may refer to a path passing through the first cell array chip CAC1, the first peripheral circuit chip PC1, and the first I/O unit IOC_A1. In this case, the memory device 200b may process the input and output of the first data DATA1 related to the first memory cell array MCA1 by using the first page buffer circuit PBC1 and the first I/O circuit 301.

In an embodiment, the memory device 200b may write second data DATA2 to the second cell array chip CAC2 or read the second data DATA2 from the second cell array chip CAC2 through the second path PATH2. The second path PATH2 may refer to a path passing through the second cell array chip CAC2, the second peripheral circuit chip PC2, and the second I/O unit IOC_A2. In this case, the memory device 200b may process the input and output of the second data DATA2 related to the second memory cell array MCA2 by using the second page buffer circuit PBC2 and the second I/O circuit 302.

The memory device 200b may perform 2-channel communication with a memory controller 100. The memory device 200b may transmit and receive the first data DATA1 to and from the memory controller 100 through the first bonding pad PD1 in response to a first command received from the memory controller 100. The memory device 200b may transmit and receive the second data DATA2 to and from the memory controller 100 through the second bonding pad PD2 in response to a second command received from the memory controller 100. In this case, the second command may be a different command from the first command.

In an embodiment, a size unit of the first data DATA1 and the second data DATA2 that are input and output between the memory device 200b and the memory controller 100 may be 16 bits. In this case, the memory device 200b may operate as a wide I/O interface. The first data DATA1 may correspond to 16-bit data, and the second data DATA2 may also correspond to 16-bit data.

In an embodiment, a size unit of the first data DATA1 and the second data DATA2 that are input and output between the memory device 200b and the memory controller 100 may be 8 bits. In this case, the first data DATA1 may correspond to 8-bit data, and the second data DATA2 may also correspond to 8-bit data.

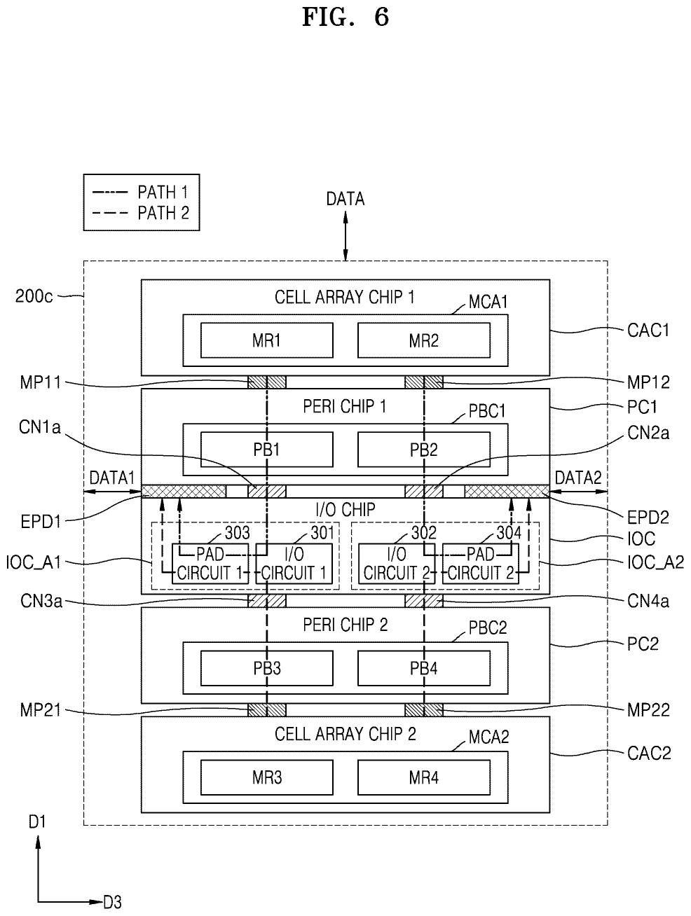

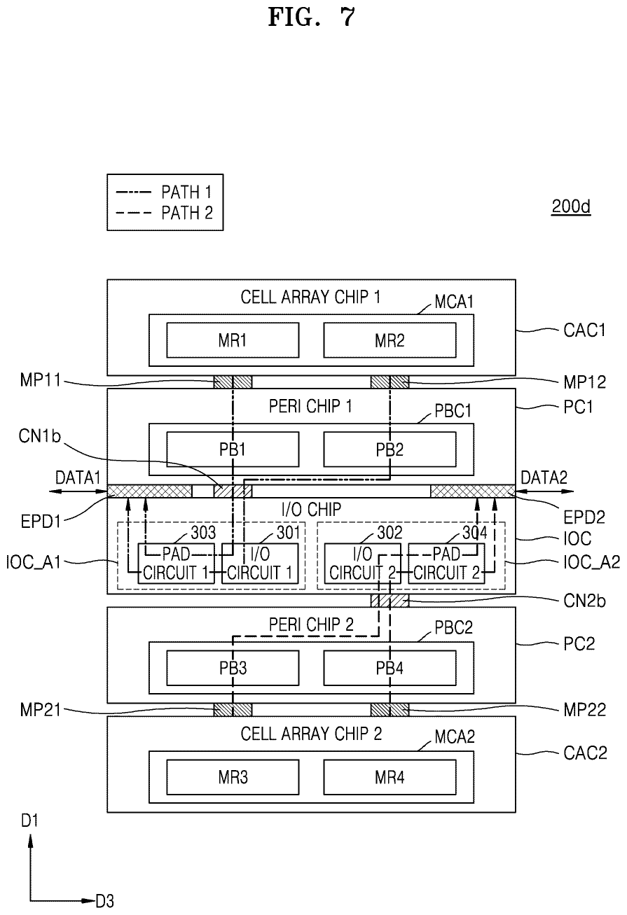

FIGS. 6 and 7 are views illustrating a memory device 200c and a memory device 200d according to embodiments. Specifically, each of FIGS. 6 and 7 corresponds to a cross-section of the memory device 200, which is taken along line I-I′ of FIG. 3. FIGS. 6 and 7 may be described with reference to FIGS. 4 and 5, and repeated descriptions may be omitted.

Referring to FIG. 6, the memory device 200c may include a component corresponding to the memory device 200a of FIG. 4. Hereinafter, repeated descriptions may be omitted, and the description below focuses on differences between the memory device 200c of FIG. 6 and the memory device 200a of FIG. 4.

The memory device 200c of FIG. 6 may include a first edge pad EPD1 and a second edge pad EPD2. The first edge pad EPD1 may be a component corresponding to the first bonding pad PD1 of the memory device 200a of FIG. 4. The second edge pad EPD2 may be a component corresponding to the second bonding pad PD2 of the memory device 200a of FIG. 4. The first edge pad EPD1 may be electrically connected to a first pad circuit 303. The second edge pad EPD2 may be electrically connected to the second pad circuit 304.

The first edge pad EPD1 and the second edge pad EPD2 may be apart from each other in a third direction D3. The first edge pad EPD1 and the second edge pad EPD2 may be between a first peripheral circuit chip PC1 and an I/O chip IOC. However, embodiments of the present disclosure are not limited thereto, and the first edge pad EPD1 and the second edge pad EPD2 may be disposed between a second peripheral circuit chip PC2 and the I/O chip IOC.

In an embodiment, the first edge pad EPD1 and the second edge pad EPD2 may be electrically connected to a memory controller 100 by using a wire bonding process.

In an embodiment, the first edge pad EPD1 and the second edge pad EPD2 may be electrically connected to the memory controller 100 through a film cable.

In an embodiment, the first edge pad EPD1 and the second edge pad EPD2 may be electrically connected to the memory controller 100 through a conductive epoxy material.

Referring to FIG. 7, the memory device 200d may include a component corresponding to the memory device 200b of FIG. 5. Hereinafter, repeated descriptions may be omitted, and the description below focuses on differences between the memory device 200d of FIG. 7 and the memory device 200b of FIG. 5.

The memory device 200d of FIG. 7 may include a first edge pad EPD1 and a second edge pad EPD2. The first edge pad EPD1 may be a component corresponding to the first bonding pad PD1 of the memory device 200b of FIG. 5. The second edge pad EPD2 may include a component corresponding to the second bonding pad PD2 of the memory device 200b of FIG. 5. In the memory device 200d of FIG. 7, the first edge pad EPD1 and the second edge pad EPD2 may be arranged at the same positions as in FIG. 6, and thus, repeated descriptions may be omitted.

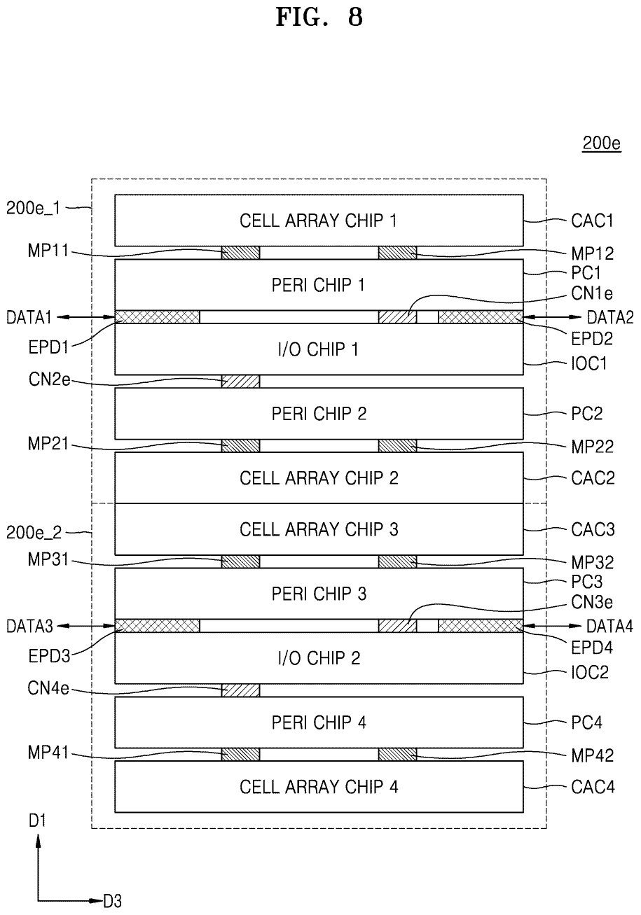

FIG. 8 is a view illustrating a memory device 200e according to embodiments. FIG. 8 may be described with reference to FIGS. 6 and 7, and repeated descriptions may be omitted.

Referring to FIG. 8, the memory device 200e may be obtained by stacking a plurality of the memory device 200d of FIG. 7 in two stages. However, embodiments of the present disclosure are not limited to an example in which a plurality of the memory device 200d of FIG. 7 are stacked in two stages. In another case, a plurality of the memory device 200c of FIG. 6 may be stacked in two stages. Also, at least two memory devices may be stacked.

The memory device 200e of FIG. 8 may include a first memory device 200e_1 and a second memory device 200e_2. The first memory device 200e_1 may include a first cell array chip CAC1, a first peripheral circuit chip PC1, a first I/O chip IOC1, a second peripheral circuit chip PC2, and a second cell array chip CAC2. The second memory device 200e_2 may include a third cell array chip CAC3, a third peripheral circuit chip PC3, a second I/O chip IOC2, a fourth peripheral circuit chip PC4, and a fourth cell array chip CAC4.

The first peripheral circuit chip PC1 may be under the first cell array chip CAC1. The first I/O chip IOC1 may be under the first peripheral circuit chip PC1. The second peripheral circuit chip PC2 may be under the first I/O chip IOC1. The second cell array chip CAC2 may be under the second peripheral circuit chip PC2. The third cell array chip CAC3 may be under the second cell array chip CAC2. The third peripheral circuit chip PC3 may be under the third cell array chip CAC3. The second I/O chip IOC2 may be under the third peripheral circuit chip PC3. The fourth peripheral circuit chip PC4 may be under the second I/O chip IOC2. The fourth cell array chip CAC4 may be under the fourth peripheral circuit chip PC4.

The first cell array chip CAC1 and the first peripheral circuit chip PC1 may be bonded to each other through the metal patterns MP11 and MP12. The second cell array chip CAC2 and the second peripheral circuit chip PC2 may be bonded to each other through the metal patterns MP21 and MP22. The third cell array chip CAC3 and the third peripheral circuit chip PC3 may be bonded to each other through the metal patterns MP31 and MP32. The fourth cell array chip CAC4 and the fourth peripheral circuit chip PC4 may be bonded to each other through the metal patterns MP41 and MP42.

The first peripheral circuit chip PC1 and the first I/O chip IOC1 may be electrically connected to each other through a first connection unit CN1e. The second peripheral circuit chip PC2 and the first I/O chip IOC1 may be electrically connected to each other through a second connection unit CN2e. The third peripheral circuit chip PC3 and the second I/O chip IOC2 may be electrically connected to each other through a third connection unit CN3e. The fourth peripheral circuit chip PC4 and the second I/O chip IOC2 may be electrically connected to each other through a fourth connection unit CN4e. However, the second cell array chip CAC2 and the third cell array chip CAC3 may not be electrically connected to each other, and may only be physically connected to each other by adhesives or insulating materials.

The first memory device 200e_1 may provide first data DATA1 and second data DATA2 to the memory controller 100 or receive the first data DATA1 and the second data DATA2 from the memory controller 100 in response to a command received from a memory controller 100.

The second memory device 200e_2 may provide third data DATA3 and fourth data DATA4 to the memory controller 100 or receive the third data DATA3 and the fourth data DATA4 from the memory controller 100 in response to a command received from the memory controller 100.

In an embodiment, a first edge pad EPD1 may be electrically connected to a third edge pad EPD3 by using a wire bonding process. A second edge pad EPD2 may be electrically connected to a fourth edge pad EPD4 by using a wire bonding process. The third edge pad EPD3 and the fourth edge pad EPD4 may be electrically connected to an external device by using a wire bonding process.

In an embodiment, the first edge pad EPD1 may be electrically connected to the third edge pad EPD3 through a film cable. The second edge pad EPD2 may be electrically connected to the fourth edge pad EPD4 through a film cable. The third edge pad EPD3 and the fourth edge pad EPD4 may be electrically connected to an external device through a film cable.

In an embodiment, the first edge pad EPD1 may be electrically connected to the third edge pad EPD3 through a conductive epoxy material. The second edge pad EPD2 may be electrically connected to the fourth edge pad EPD4 through a conductive epoxy material. The third edge pad EPD3 and the fourth edge pad EPD4 may be electrically connected to an external device through a conductive epoxy material.

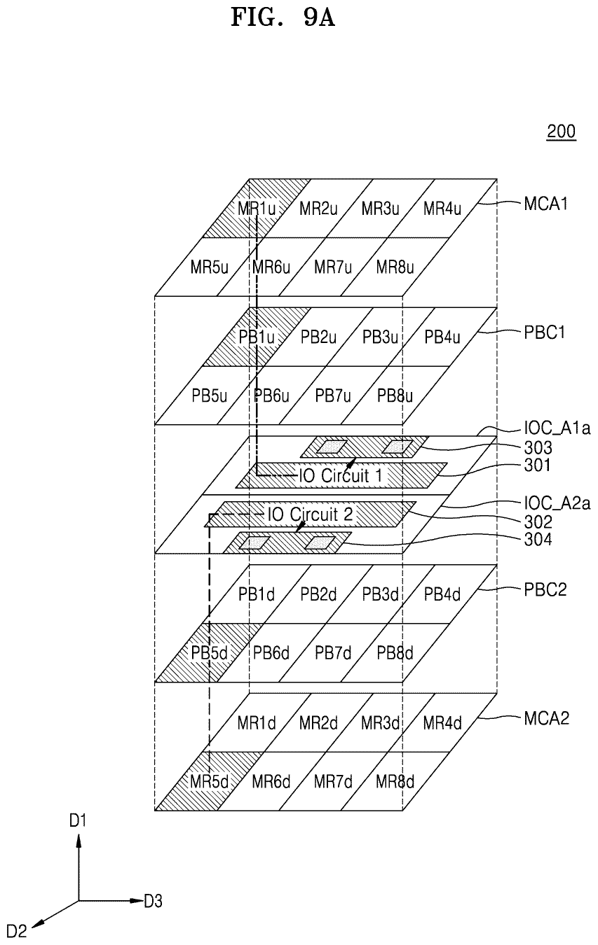

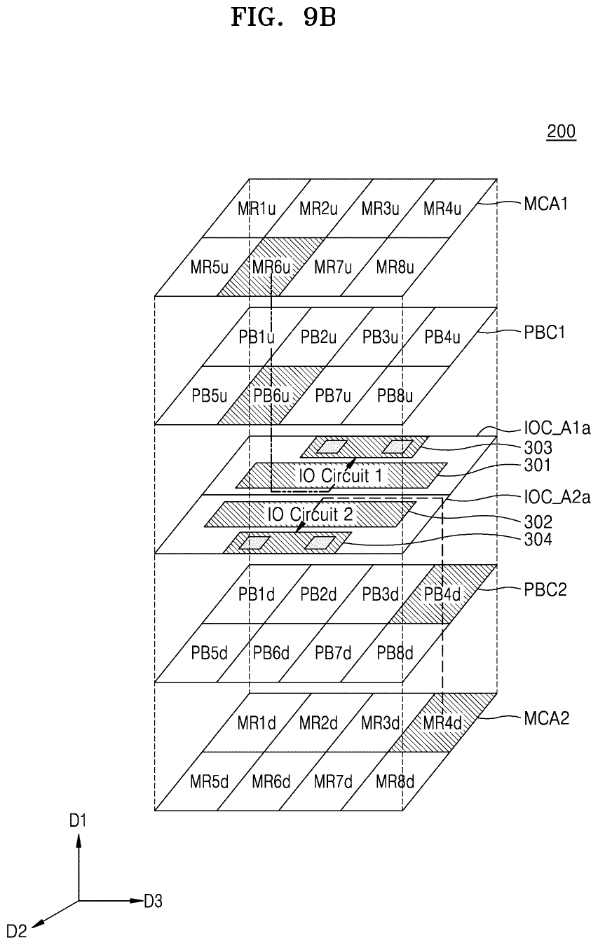

FIGS. 9A and 9B are views illustrating an operating method of a memory device 200 according to embodiments. FIGS. 9A and 9B may be described with reference to FIGS. 1 to 5, and repeated descriptions may be omitted.

Referring to FIGS. 9A and 9B, the memory device 200 may include a first memory cell array MCA1, a first page buffer circuit PBC1, a first I/O unit IOC_A1a, a second I/O unit IOC_A2a, a second page buffer circuit PBC2, and a second memory cell array MCA2.

The first memory cell array MCA1 may be formed in the first cell array chip CAC1 of FIG. 1. The first memory cell array MCA1 may include first to eighth memory regions MR1u to MR8u. Although the first memory cell array MCA1 is illustrated as including eight memory regions as an example, the first memory cell array MCA1 may include fewer or more memory regions than in FIGS. 9A and 9B.

The first page buffer circuit PBC1 may be formed in the first peripheral circuit chip PC1 of FIG. 1. The first page buffer circuit PBC1 may include first to eighth page buffers PB1u to PB8u. Although the first page buffer circuit PBC1 is illustrated as including eight page buffers as an example, the first page buffer circuit PBC1 may include fewer or more page buffers than in FIGS. 9A and 9B.

In an embodiment, the first to eighth page buffers PB1u to PB8u may respectively overlap with the first to eighth memory regions MR1u to MR8u in a first direction D1. For example, the first memory region MR1u and the first page buffer PB1u may overlap each other in the first direction D1. For example, the sixth memory region MR6u and the sixth page buffer PB6u may overlap each other in the first direction D1.

The first I/O unit IOC_A1a and the second I/O unit IOC_A2a may be formed in the I/O chip IOC of FIG. 1. The first I/O unit IOC_A1a may include a first I/O circuit 301 and a first pad circuit 303. The second I/O unit IOC_A2a may include a second I/O circuit 302 and a second pad circuit 304. The first I/O unit IOC_A1a and the second I/O unit IOC_A2a may be apart from each other in a second direction D2. The first I/O circuit 301 and the first pad circuit 303 may be apart from each other in the second direction D2 and may be electrically connected to each other through a wiring. The second I/O circuit 302 and the second pad circuit 304 may be apart from each other in the second direction D2 and may be electrically connected to each other through a wiring.

The second page buffer circuit PBC2 may be formed in the second peripheral circuit chip PC2 of FIG. 1. The second page buffer circuit PBC2 may include first to eighth page buffers PB1d to PB8d. Although the second page buffer circuit PBC2 is illustrated as including eight page buffers as an example, the second page buffer circuit PBC2 may include fewer or more page buffers than in FIGS. 9A and 9B.

The second memory cell array MCA2 may be formed in the second cell array chip CAC2 of FIG. 1. The second memory cell array MCA2 may include first to eighth memory regions MR1d to MR8d. Although the second memory cell array MCA2 is illustrated as including eight memory regions as an example, the second memory cell array MCA2 may include fewer or more memory regions than in FIGS. 9A and 9B.

In an embodiment, the first to eighth page buffers PB1d to PB8d may respectively overlap with the first to eighth memory regions MR1d to MR8d in the first direction D1. For example, the fourth memory region MR4d and the fourth page buffer PB4d may overlap each other in the first direction D1. For example, the fifth memory region MR5d and the fifth page buffer PB5d may overlap each other in the first direction D1.

In an embodiment, the first page buffer circuit PBC1 may be formed on one surface of the first peripheral circuit chip PC1 of FIG. 1, and the first I/O unit IOC_A1a and the second I/O unit IOC_A2a may be formed on another surface of the first peripheral circuit chip PC1 of FIG. 1.

In an embodiment, the second page buffer circuit PBC2 may be formed on one surface of the second peripheral circuit chip PC2 of FIG. 1, and the first I/O unit IOC_A1a and the second I/O unit IOC_A2a may be formed on another surface of the second peripheral circuit chip PC2 of FIG. 1.

When reading data stored in the first memory cell array MCA1 or when writing data to the first memory cell array MCA1, the memory device 200 may perform an operation of reading or writing data by using the first page buffer circuit PBC1 and the first I/O unit IOC_A1a.

In an embodiment, referring to FIG. 9A, the memory device 200 may read data from the first memory region MR1u or write data to the first memory region MR1u through the first page buffer PB1u and the first I/O circuit 301.

In an embodiment, referring to FIG. 9B, the memory device 200 may read data from the sixth memory region MR6u or write data to the sixth memory region MR6u through the sixth page buffer PB6u and the first I/O circuit 301.

When reading data stored in the second memory cell array MCA2 or writing data to the second memory cell array MCA2, the memory device 200 may perform an operation of reading or writing data by using the second page buffer circuit PBC2 and the second I/O unit IOC_A2a.

In an embodiment, referring to FIG. 9A, the memory device 200 may read data from the fifth memory region MR5d or write data to the fifth memory region MR5d through the fifth page buffer PB5d and the second I/O circuit 302.

In an embodiment, referring to FIG. 9B, the memory device 200 may read data from the fourth memory region MR4d or write data to the fourth memory region MR4d through the fourth page buffer PB4d and the second I/O circuit 302.

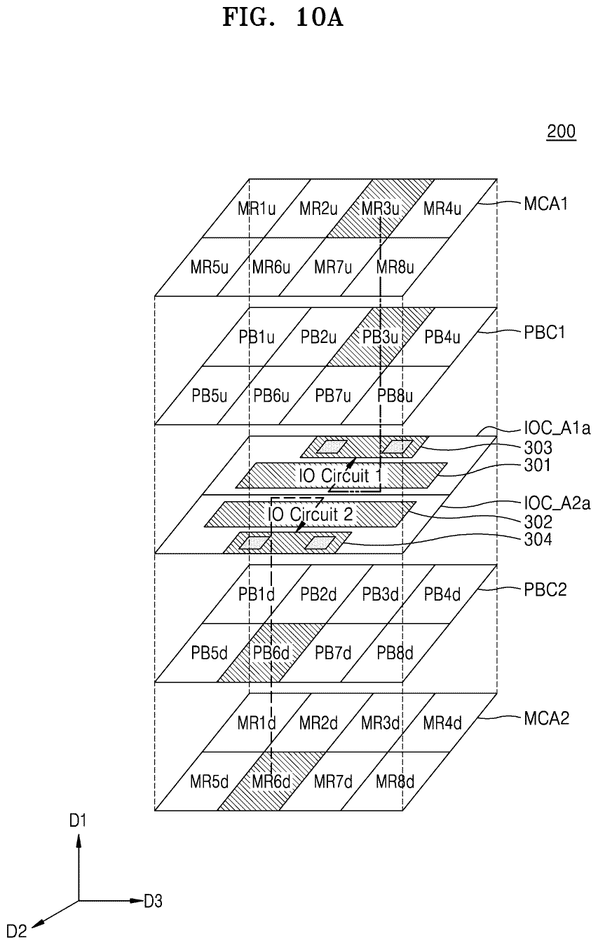

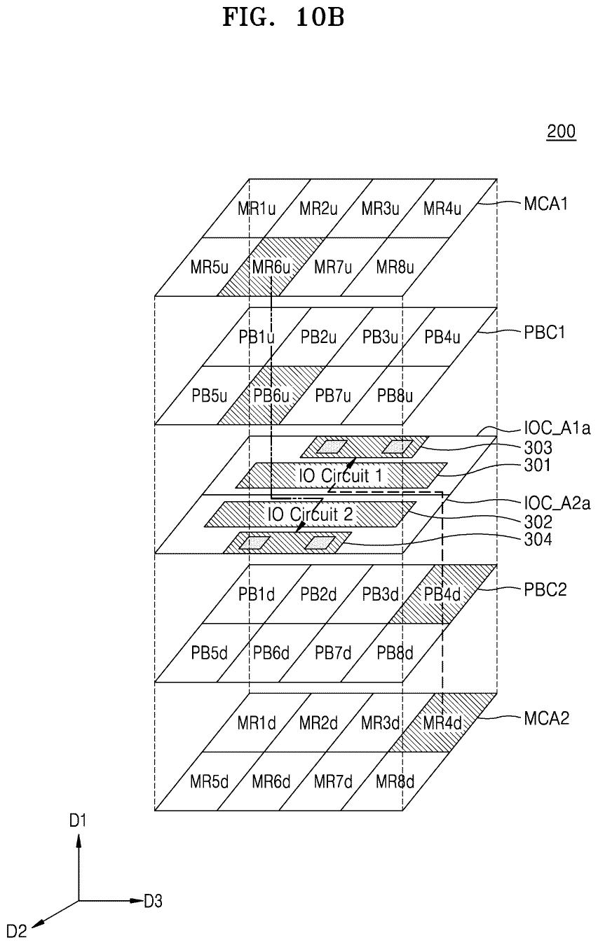

FIGS. 10A and 10B are views illustrating an operating method of a memory device 200 according to embodiments. FIGS. 10A and 10B may be described with reference to FIGS. 1 to 5, 9A, and 9B, and repeated descriptions may be omitted.

The description below focuses on differences between operations of the memory device 200 shown in FIGS. 10A and 10B and the operations of the memory device 200 shown in FIGS. 9A and 9B.

Referring to FIGS. 10A and 10B, when reading or writing data from or to memory regions included a first memory cell array MCA1, the memory device 200 may perform an operation of reading or writing data by using an I/O circuit that is close to each memory region.

In an embodiment, referring to FIG. 10A, the memory device 200 may read data from a third memory region MR3u or write data to the third memory region MR3u through a third page buffer PB3u and a first I/O circuit 301. In this case, a distance between the third memory region MR3u and the first I/O circuit 301 may be less than a distance between the third memory region MR3u and a second I/O circuit 302.

In an embodiment, referring to FIG. 10B, the memory device 200 may read data from a sixth memory region MR6u or write data to the sixth memory region MR6u through a sixth page buffer PB6u and a second I/O circuit 302. In this case, a distance between the sixth memory region MR6u and the second I/O circuit 302 may be less than a distance between the sixth memory region MR6u and the first I/O circuit 301.

When reading or writing data from or to memory regions included in a second memory cell array MCA2, the memory device 200 may perform an operation of reading or writing data through an I/O circuit that is close to each memory region.

In an embodiment, referring to FIG. 10A, the memory device 200 may read data from a sixth memory region MR6d or write data to the sixth memory region MR6d through a sixth page buffer PB6d and the second I/O circuit 302. In this case, a distance between the sixth memory region MR6d and the second I/O circuit 302 may be less than a distance between the sixth memory region MR6d and the first I/O circuit 301.

In an embodiment, referring to FIG. 10B, the memory device 200 may read data from a fourth memory region MR4d or write data to the fourth memory region MR4d through a fourth page buffer PB4d and the first I/O circuit 301. In this case, a distance between the fourth memory region MR4d and the first I/O circuit 301 may be less than a distance between the fourth memory region MR4d and the second I/O circuit 302.

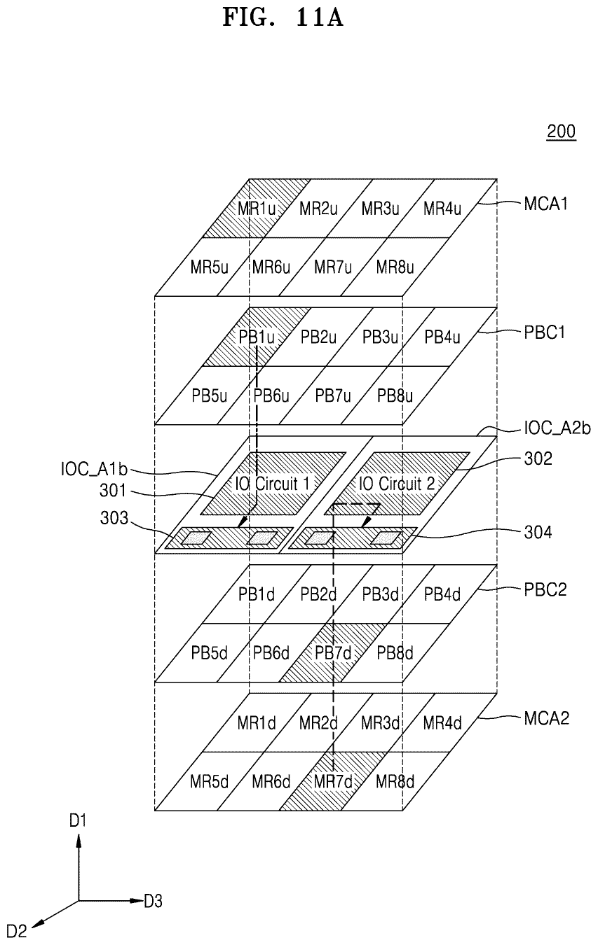

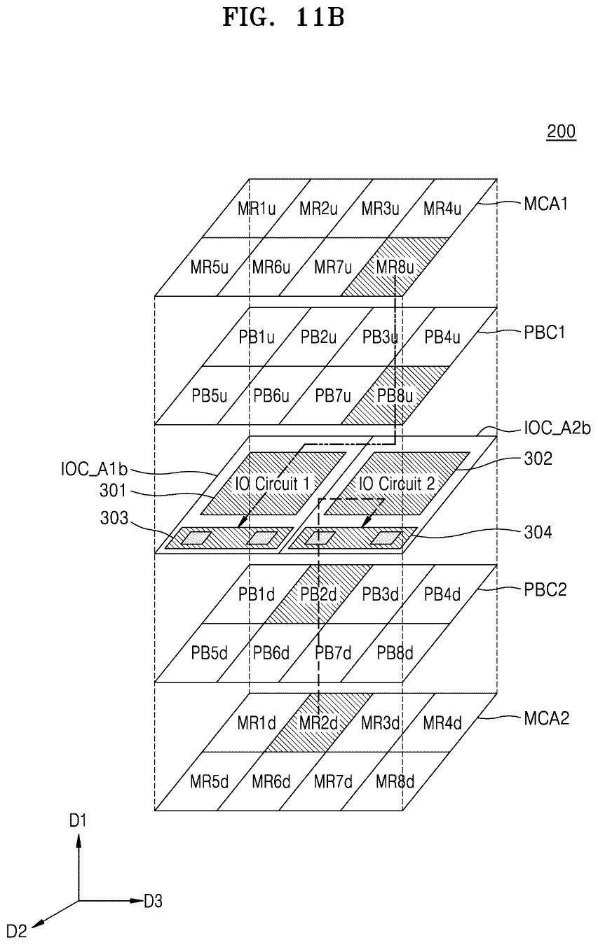

FIGS. 11A and 11B are views illustrating an operating method of a memory device 200 according to embodiments. FIGS. 11A and 11B may be described with reference to FIGS. 1 to 5, 9A, and 9B, and repeated descriptions may be omitted.

The description below focuses on differences between operations of the memory device 200 shown in FIGS. 11A and 11B and the operations of the memory device 200 shown in FIGS. 9A and 9B.

Referring to FIGS. 11A and 11B, unlike the first I/O unit IOC_A1a and the second I/O unit IOC_A2a of FIGS. 9A and 9B, a first I/O unit IOC_A1b and a second I/O unit IOC_A2b of FIGS. 11A and 11B may be apart from each other in a third direction D3. The first pad circuit 303 and the second pad circuit 304 may be apart from each other in the third direction D3. A first I/O circuit 301 and the first pad circuit 303 may be apart from each other in a second direction D2 and may be electrically connected to each other through a wiring. A second I/O circuit 302 and the second pad circuit 304 may be apart from each other in the second direction D2 and may be electrically connected to each other through a wiring.

When reading data stored in a first memory cell array MCA1 or when writing data to the first memory cell array MCA1, the memory device 200 may perform an operation of reading or writing data by using a first page buffer circuit PBC1 and the first I/O unit IOC_A1a.

In an embodiment, referring to FIG. 11A, the memory device 200 may read data from a first memory region MR1u or write data to the first memory region MR1u through a first page buffer PB1u and the first I/O circuit 301.

In an embodiment, referring to FIG. 11B, the memory device 200 may read data from an eighth memory region MR8u or write data to the eighth memory region MR8u through an eighth page buffer PB8u and the first I/O circuit 301.

When reading data stored in a second memory cell array MCA2 or when writing data to the second memory cell array MCA2, the memory device 200 may perform an operation of reading or write data by using a second page buffer circuit PBC2 and the second I/O unit IOC_A2a.

In an embodiment, referring to FIG. 11A, the memory device 200 may read data from a seventh memory region MR7d or write data to the seventh memory region MR7d through a seventh page buffer PB7s and the second I/O circuit 302.

In an embodiment, referring to FIG. 11B, the memory device 200 may read data from a second memory region MR2d or write data to the second memory region MR2d through the second page buffer PB2d and the second I/O circuit 302.

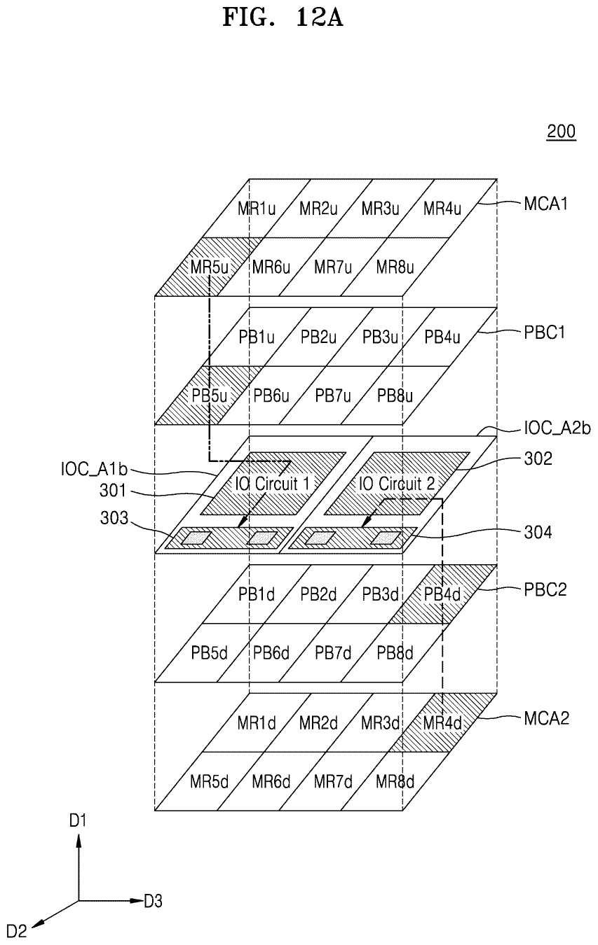

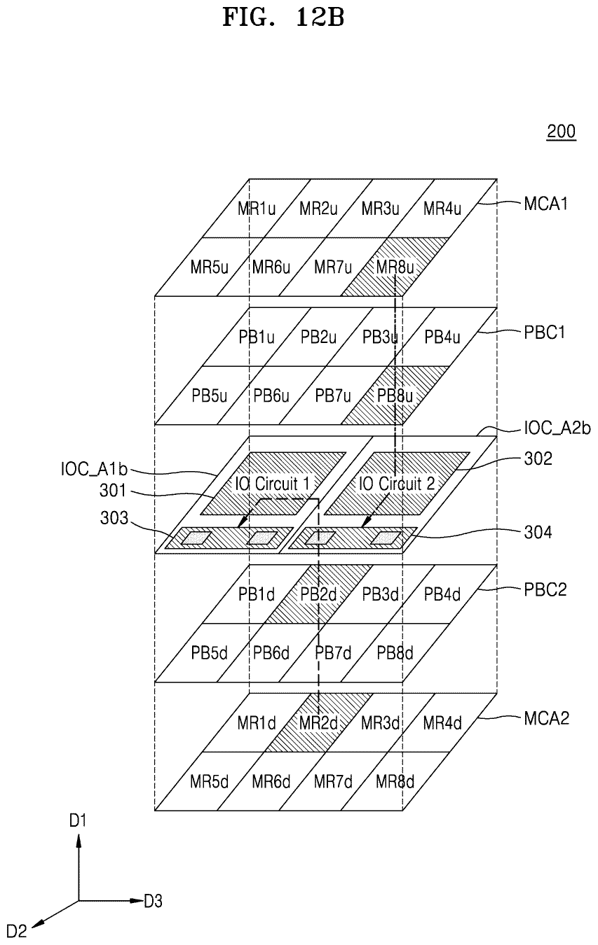

FIGS. 12A and 12B are views illustrating an operating method of a memory device 200 according to embodiments. FIGS. 12A and 12B may be described with reference to FIGS. 1 to 5, 11A, and 11B, and repeated descriptions may be omitted.

The description below focuses on differences between operations of the memory device 200 shown in FIGS. 12A and 12B and the operations of the memory device 200 shown in FIGS. 11A and 11B.

Referring to FIGS. 12A and 12B, when reading or writing data from or to memory regions included in a first memory cell array MCA1, the memory device 200 may perform an operation of reading or writing data by using an I/O circuit that is close to each of the memory regions.

In an embodiment, referring to FIG. 12A, the memory device 200 may read data from a fifth memory region MR5u or write data to the fifth memory region MR5u through a fifth page buffer PB5u and a first I/O circuit 301. In this case, a distance between the fifth memory region MR5u and the first I/O circuit 301 may be less than a distance between the fifth memory region MR5u and a second I/O circuit 302.

In an embodiment, referring to FIG. 12B, the memory device 200 may read data from an eighth memory region MR8u or write data to the eighth memory region MR8u through an eighth page buffer PB8u and the second I/O circuit 302. In this case, a distance between the eighth memory region MR8u and the second I/O circuit 302 may be less than a distance between the eighth memory region MR8u and the first I/O circuit 301.

When reading or writing data from or to memory regions included in a second memory cell array MCA2, the memory device 200 may perform an operation of reading or writing data by using an I/O circuit that is close to each of the memory regions.

In an embodiment, referring to FIG. 12A, the memory device 200 may read data from a fourth memory region MR4d or write data to the fourth memory region MR4d through a fourth page buffer PB4d and the second I/O circuit 302. In this case, a distance between the fourth memory region MR4d and the second I/O circuit 302 may be less than a distance between the fourth memory region MR4d and the first I/O circuit 301.

In an embodiment, referring to FIG. 12B, the memory device 200 may read data from a second memory region MR2d or write data to the second memory region MR2d through a second page buffer PB2d and the first I/O circuit 301. In this case, a distance between the second memory region MR2d and the first I/O circuit 301 may be less than a distance between the second memory region MR2d and the second I/O circuit 302.

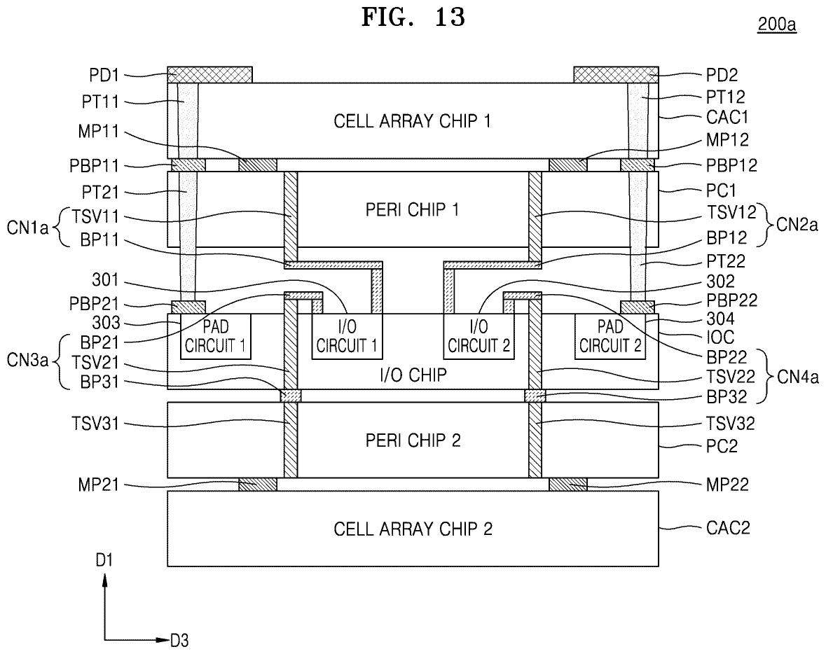

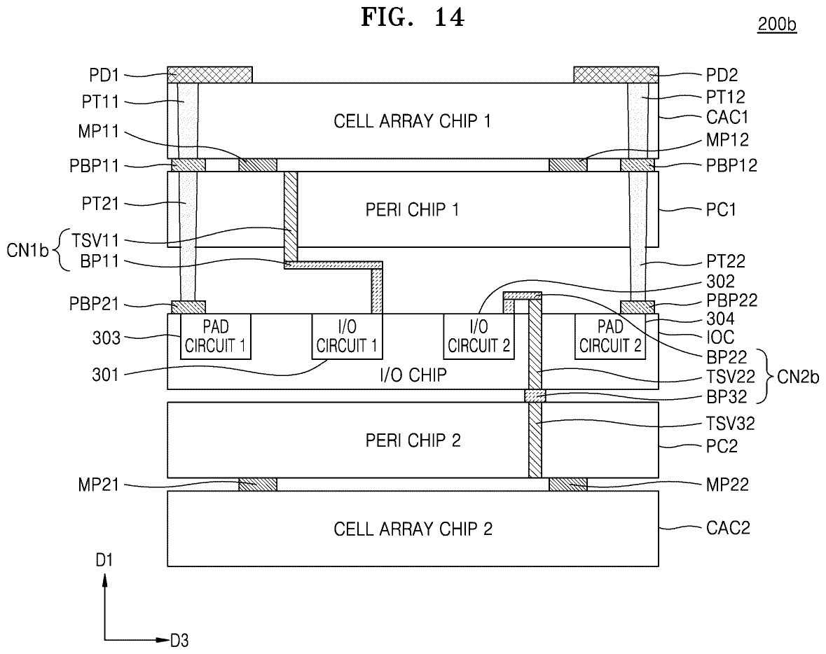

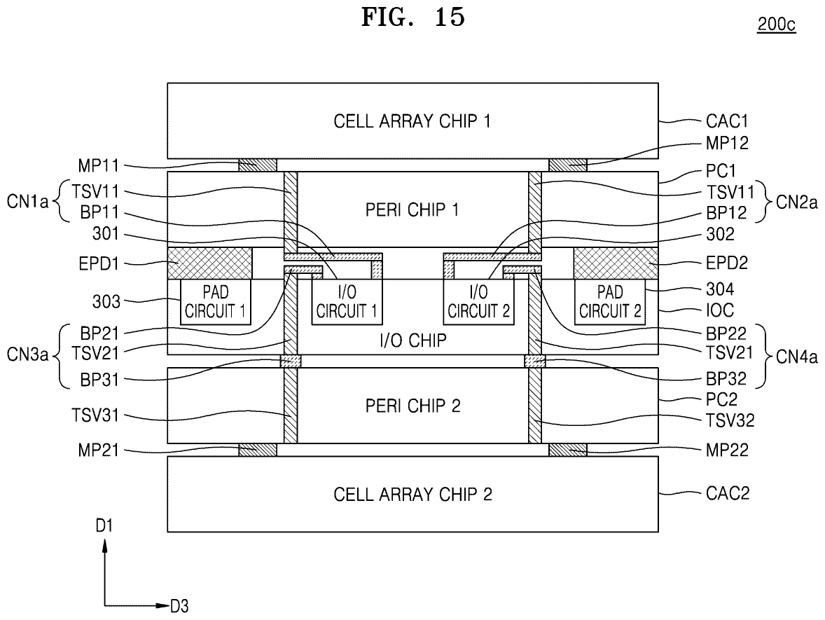

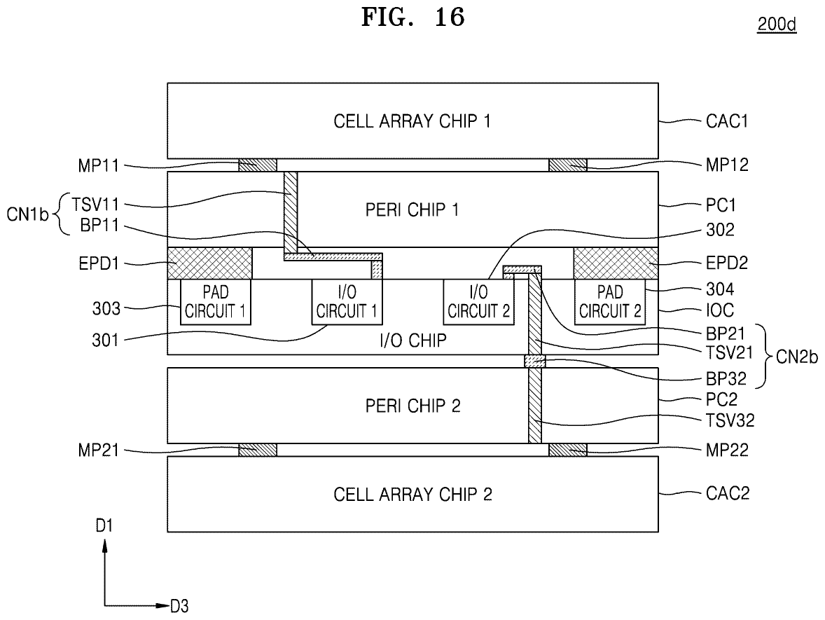

FIGS. 13 to 16 are respectively views illustrating the memory device 200a, a memory device 200b, the memory device 200c, and the memory device 200d according to embodiments. Specifically, FIG. 13 is a view illustrating connection between chips included in the memory device 200a of FIG. 4. FIG. 14 is a view illustrating connection between chips included in the memory device 200b of FIG. 5. FIG. 15 is a view illustrating connection between chips included in the memory device 200c of FIG. 6. FIG. 16 is a view illustrating connection between chips included in the memory device 200d of FIG. 7. FIGS. 13 to 16 may be described with reference to FIGS. 4 to 7, and repeated descriptions may be omitted.

Referring to FIGS. 13 and 15, a first peripheral circuit chip PC1 may be electrically connected to an I/O chip IOC through a first connection unit CN1a and a second connection unit CN2a. The first connection unit CN1a may include a through-silicon via (TSV) TSV11 and a TSV connection unit BP11. the second connection unit CN2a may include a TSV TSV12 and a TSV connection unit BP12. A second peripheral circuit chip PC2 may be electrically connected to the I/O chip IOC through a third connection unit CN3a and a fourth connection unit CN4a. The third connection unit CN3a may include a TSV TSV21, a TSV connection unit BP21, and a TSV connection unit BP31. The fourth connection unit CN4a may include a TSV TSV22, a TSV connection unit BP22, and a TSV connection unit BP32.

The TSV TSV11 may pass through the first peripheral circuit chip PC1 and be electrically connected to the TSV connection unit BP11. The TSV connection unit BP11 and the TSV connection unit BP21 may be electrically connected to a first I/O circuit 301. The TSV TSV21 may pass through the I/O chip IOC and be electrically connected to the TSV connection unit BP21 and the TSV connection unit BP31. A TSV TSV31 may pass through the second peripheral circuit chip PC2 and electrically connect the TSV connection unit BP31 to components included in the second peripheral circuit chip PC2. The TSV TSV12 may pass through the first peripheral circuit chip PC1 and be electrically connected to the TSV connection unit BP12. The TSV connection unit BP12 and the TSV connection unit BP22 may be electrically connected to a second I/O circuit 302. The TSV TSV22 may pass through the I/O chip IOC and be electrically connected to the TSV connection unit BP22 and the TSV connection unit BP32. A TSV TSV32 may pass through the second peripheral circuit chip PC2 and electrically connect the TSV connection unit BP32 to components included in the second peripheral circuit chip PC2.

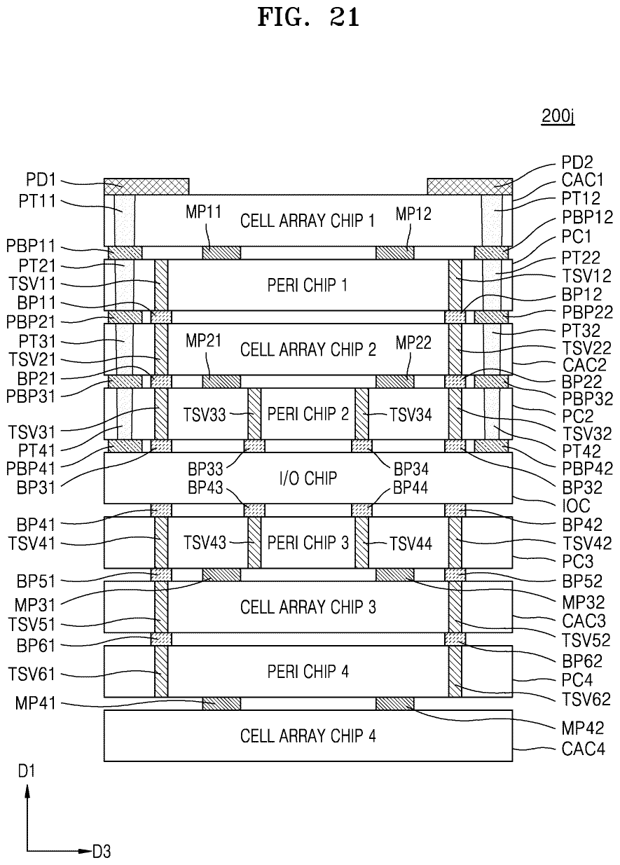

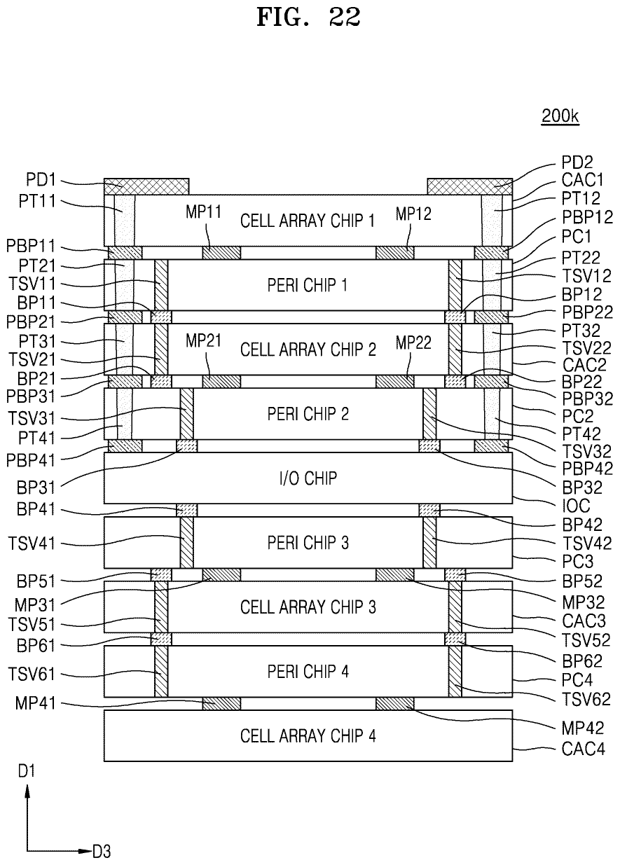

Referring to FIGS. 14 and 16, the first peripheral circuit chip PC1 may be electrically connected to the I/O chip IOC through a first connection unit CN1b. The first connection unit CN1b may include a TSV TSV11 and a TSV connection unit BP11. The TSV TSV11 may pass through the first peripheral circuit chip PC1 and be electrically connected to the TSV connection unit BP11. The TSV connection unit BP11 may be electrically connected to a TSV TSV61 (e.g., refer to FIGS. 21-22) through the first I/O circuit 301.

The second peripheral circuit chip PC2 may be electrically connected to the I/O chip IOC through a second connection unit CN2b. The second connection unit CN2b may include a TSV TSV22, a TSV connection unit BP22, and a TSV connection unit BP32. The TSV TSV22 may pass through the I/O chip IOC and be electrically connected to the TSV connection unit BP22. The TSV connection unit BP22 may be electrically connected to the TSV TSV61 (e.g., refer to FIGS. 21-22) through the second I/O circuit 302. A TSV TSV32 may pass through the second peripheral circuit chip PC2 and electrically connect components included in the second peripheral circuit chip PC2 to the TSV connection unit BP32.

Referring to FIGS. 13 and 14, the contact plug PT21 may be electrically connected to the first pad circuit 303 through the contact bonding pad PBP21. The contact plug PT22 may be electrically connected to the second pad circuit 304 through the contact bonding pad PBP22.

As used herein, a TSV connection unit may refer to a component provided for electrically connection between a TSV and another component.

In an embodiment, the TSV connection units BP11, BP12, BP21, BP22, BP31, and BP32 may include conductive pads. The conductive pads may include copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof.

In an embodiment, the TSV connection units BP11, BP12, BP21, BP22, BP31, and BP32 may include conductive bumps. The conductive bumps may include a metal, such as tin (Sn), copper (Cu), silver (Ag), gold (Au), tungsten (W), bismuth (Bi), zirconium (Zr), zinc (Zn), cobalt (Co), and nickel (Ni), or an alloy thereof.

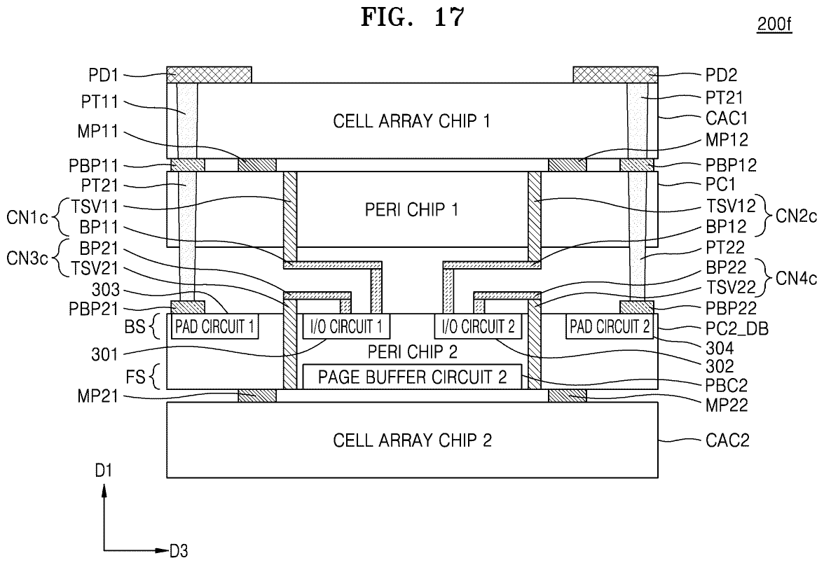

FIGS. 17 to 20 are views respectively illustrating a memory device 200f, a memory device 200g, a memory device 200h, and a memory device 200i according to embodiments. FIGS. 17 to 20 may be described with reference to FIGS. 13 to 16, and repeated descriptions may be omitted.

Referring to FIG. 17, the memory device 200f of FIG. 17 may correspond to the memory device 200a of FIG. 13. However, the memory device 200f of FIG. 17 may not include the I/O chip IOC unlike the memory device 200a of FIG. 13, and a second peripheral circuit chip PC2_DB of the memory device 200f of FIG. 17 may include components included in the I/O chip IOC of FIG. 13.

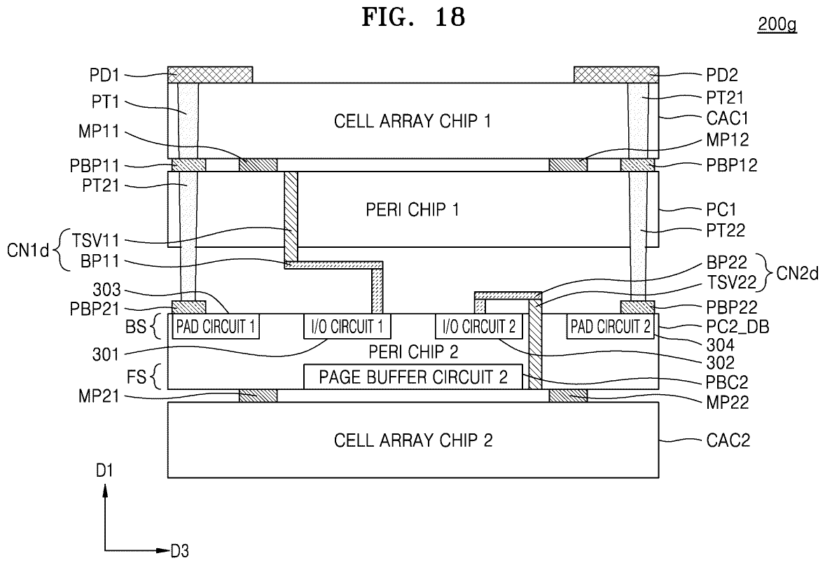

Referring to FIG. 18, the memory device 200g of FIG. 18 may correspond to the memory device 200b of FIG. 14. However, the memory device 200g of FIG. 18 may not include an I/O chip IOC unlike the memory device 200b of FIG. 14, and a second peripheral circuit chip PC2_DB of the memory device 200g of FIG. 18 may include components included in the I/O chip IOC of FIG. 14.

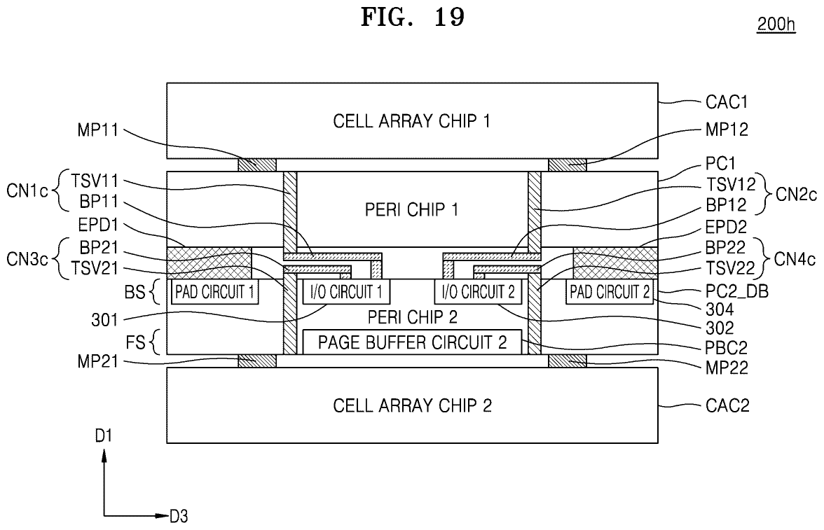

Referring to FIG. 19, the memory device 200h of FIG. 19 may correspond to the memory device 200c of FIG. 15. However, the memory device 200h of FIG. 19 may not include an I/O chip IOC unlike the memory device 200c of FIG. 15, and a second peripheral circuit chip PC2_DB of the memory device 200h of FIG. 19 may include components included in the I/O chip IOC of FIG. 15.

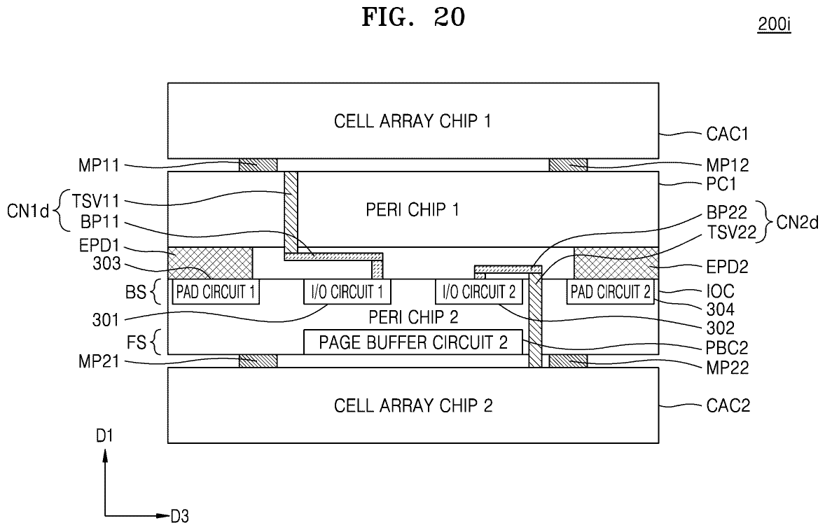

Referring to FIG. 20, the memory device 200i of FIG. 20 may correspond to the memory device 200d of FIG. 16. However, the memory device 200i of FIG. 20 may not include an I/O chip IOC unlike the memory device 200d of FIG. 16, and a second peripheral circuit chip PC2_DB of the memory device 200h of FIG. 20 may include components included in the I/O chip IOC of FIG. 16.

In FIGS. 17 to 20, the second peripheral circuit chip PC2_DB is illustrated as including components included in the I/O chip IOC of FIGS. 13 to 16, and a first peripheral circuit chip PC1 of FIGS. 17 to 20 may include components included in the I/O chip IOC of FIGS. 13 to 16.

Referring to FIGS. 17 to 20, the second peripheral circuit chip PC2_DB may include a second page buffer circuit PBC2, a first I/O circuit 301, a second I/O circuit 302, a first pad circuit 303, and a second pad circuit 304. The second page buffer circuit PBC2 may be formed on a front side unit FS of the second peripheral circuit chip PC2_DB. The first I/O circuit 301, the second I/O circuit 302, the first pad circuit 303, and the second pad circuit 304 may be formed on a back side unit BS of the second peripheral circuit chip PC2_DB.

Referring to FIGS. 17 and 19, the first peripheral circuit chip PC1 may be electrically connected to the back side unit BS of the second peripheral circuit chip PC2_DB through a first connection unit CN1c and a second connection unit CN2c.

The first connection unit CN1c may include a TSV TSV11 and a TSV connection unit BP11. The TSV TSV11 may pass through the first peripheral circuit chip PC1 and be electrically connected to the TSV connection unit BP11. The TSV connection unit BP11 may be electrically connected to the first I/O circuit 301.

The second connection unit CN2c may include a TSV TSV12 and a TSV connection unit BP12. The TSV TSV12 may pass through the first peripheral circuit chip PC1 and be electrically connected to the TSV connection unit BP12. The TSV connection unit BP12 may be electrically connected to the second I/O circuit 302. A TSV TSV22 may pass through the second peripheral circuit chip PC2_DB and be electrically connected to a TSV connection unit BP22.

The front side unit FS and the back side unit BS of the second peripheral circuit chip PC2_DB may be electrically connected to each other through a third connection unit CN3c and a fourth connection unit CN4c.

The third connection unit CN3c may include a TSV TSV21 and a TSV connection unit BP21. The TSV TSV21 may pass through the second peripheral circuit chip PC2_DB and be electrically connected to the TSV connection unit BP21. The TSV connection unit BP21 may be electrically connected to the first I/O circuit 301.

The fourth connection unit CN4c may electrically connect the front side unit FS and the back side unit BS of the second peripheral circuit chip PC2_DB to each other. The fourth connection unit CN4c may include the TSV TSV22 and the TSV connection unit BP22. The TSV TSV22 may pass through the second peripheral circuit chip PC2_DB and be electrically connected to the TSV connection unit BP22. The TSV connection unit BP22 may be electrically connected to the second I/O circuit 302.

Referring to FIGS. 18 and 20, the first peripheral circuit chip PC1 and the second peripheral circuit chip PC2_DB may be electrically connected to each other through a first connection unit CN1d and a second connection unit CN2d.

The first connection unit CN1d may include a TSV TSV11 and a TSV connection unit BP11. The TSV TSV11 may be electrically connected to the TSV connection unit BP11 through the first peripheral circuit chip PC1. The TSV connection unit BP11 may be electrically connected to a first I/O circuit 301.

The second connection unit CN2d may include a TSV TSV22 and a TSV connection unit BP22. The TSV TSV22 may pass through the second peripheral circuit chip PC2_DB and be electrically connected to the TSV connection unit BP22. The TSV connection unit BP22 may be electrically connected to a second I/O circuit 302.

FIG. 21 is a view illustrating a memory device 200j according to embodiments.

Referring to FIG. 21, the memory device 200j may include a first cell array chip CAC1, a first peripheral circuit chip PC1, a second cell array chip CAC2, a second peripheral circuit chip PC2, an I/O chip IOC, a third peripheral circuit chip PC3, a third cell array chip CAC3, a fourth peripheral circuit chip PC4, and a fourth cell array chip CAC4. Also, the memory device 200j may include a first bonding pad PD1, a second bonding pad PD2, metal patterns MP11, MP12, MP21, MP22, MP31, MP32, MP41, and MP42, contact plugs PT11, PT12, PT21, PT22, PT31, PT32, PT41, and PT42, contact bonding pads PBP11, PBP12, PBP21, PBP22, PBP31, PBP32, PBP41, and PBP42, TSVs TSV11, TSV12, TSV21, TSV22, TSV31, TSV32, TSV33, TSV34, TSV41, TSV42, TSV43, TSV44, TSV51, TSV52, TSV61, and TSV62, and TSV connection units BP11, BP12, BP21, BP22, BP31, BP32, BP33, BP34, BP41, BP42, BP43, BP44, BP51, BP52, BP61, and BP62.

The contact plug PT11 and the contact plug PT12 may pass through the first cell array chip CAC1. The contact plug PT21 and the contact plug PT22 may pass through the first peripheral circuit chip PC1. The contact plug PT31 and the contact plug PT32 may pass through the second cell array chip CAC2. The contact plug PT41 and the contact plug PT42 may pass through the second peripheral circuit chip PC2.

The first bonding pad PD1 may be electrically connected to the contact bonding pad PBP11 through the contact plug PT11. The second bonding pad PD2 may be electrically connected to the contact bonding pad PBP12 through the contact plug PT12. The contact plug PT11 may be electrically connected to the contact plug PT21 through the contact bonding pad PBP11. The contact plug PT12 may be electrically connected to the contact plug PT22 through the contact bonding pad PBP12. The contact plug PT21 may be electrically connected to the contact plug PT31 through the contact bonding pad PBP21. The contact plug PT22 may be electrically connected to the contact plug PT32 through the contact bonding pad PBP22. The contact plug PT31 may be electrically connected to the contact plug PT41 through the contact bonding pad PBP31. The contact plug PT32 may be electrically connected to the contact plug PT42 through the contact bonding pad PBP32. The contact plug PT41 may be electrically connected to the I/O chip IOC through the contact bonding pad PBP41. The contact plug PT42 may be electrically connected to the I/O chip IOC through the contact bonding pad PBP42.

Components included in the first peripheral circuit chip PC1 may transmit and receive data to and from the I/O chip IOC through the TSVs TSV11, TSV12, TSV21, TSV22, TSV31, and TSV32. The TSV TSV11 and the TSV TSV12 may pass through the first peripheral circuit chip PC1. The TSV TSV21 and the TSV TSV22 may pass through the first cell array chip CAC1. The TSV TSV31 and the TSV TSV32 may pass through the second peripheral circuit chip PC2.

The TSVs TSV11 and TSV12 may be electrically connected to components of the first peripheral circuit chip PC1. The TSV TSV11 may be electrically connected to the TSV TSV21 through the TSV connection unit BP11. The TSV TSV12 may be electrically connected to the TSV TSV22 through the TSV connection unit BP12. The TSV TSV21 may be electrically connected to the TSV TSV31 through the TSV connection unit BP21. The TSV TSV22 may be electrically connected to the TSV TSV32 through the TSV connection unit BP22. The TSV TSV31 may be electrically connected to the I/O chip IOC through the TSV connection unit BP31. The TSV TSV32 may be electrically connected to the I/O chip IOC through the TSV connection unit BP32.

Components included in the second peripheral circuit chip PC2 may transmit and receive data to and from the I/O chip IOC through the TSVs TSV33 and TSV34. The TSVs TSV33 and TSV34 may pass through the second peripheral circuit chip PC2. The TSV TSV33 may electrically connect components included in the second peripheral circuit chip PC2 to the TSV connection unit BP33. The TSV TSV34 may electrically connect components included in the second peripheral circuit chip PC2 to the TSV connection unit BP34. The TSV connection unit BP33 may electrically connect the TSV TSV33 to the I/O chip IOC. The TSV connection unit BP34 may electrically connect the TSV TSV34 to the I/O chip IOC.

Components include in the third peripheral circuit chip PC3 may transmit and receive data to and from the I/O chip IOC through the TSVs TSV43 and TSV44. The TSVs TSV43 and TSV44 may pass through the third peripheral circuit chip PC3. The TSV TSV43 may electrically connect components included in the third peripheral circuit chip PC3 to the TSV connection unit BP43. The TSV TSV44 may electrically connect the components included in the third peripheral circuit chip PC3 to the TSV connection unit BP44. The TSV connection unit BP43 may electrically connect the TSV TSV43 to the I/O chip IOC. The TSV connection unit BP34 may electrically connect the TSV TSV34 to the I/O chip IOC.

Components included in the fourth peripheral circuit chip PC4 may transmit and receive data to and from the I/O chip IOC through the TSVs TSV41, TSV42, TSV51, TSV52, TSV61, and TSV62. The TSV TSV41 and the TSV TSV42 may pass through the third peripheral circuit chip PC3. The TSV TSV51 and the TSV TSV52 may pass through the third cell array chip CAC3. The TSV TSV61 and the TSV TSV62 may pass through the fourth peripheral circuit chip PC4.

The TSV TSV41 may be electrically connected to the TSV TSV51 through the TSV connection unit BP51. The TSV TSV42 may be electrically connected to the TSV TSV52 through the TSV connection unit BP52. The TSV TSV51 may be electrically connected to the TSV TSV61 through the TSV connection unit BP61. The TSV TSV52 may be electrically connected to the TSV TSV62 through the TSV connection unit BP62. The TSVs TSV61 and TSV62 may be electrically connected to components of the fourth peripheral circuit chip PC4.

The first bonding pad PD1 and the second bonding pad PD2 may be disposed on the first cell array chip CAC1. The first peripheral circuit chip PC1 may be under the first cell array chip CAC1. The second cell array chip CAC2 may be under the first peripheral circuit chip PC1. The second peripheral circuit chip PC2 may be under the second cell array chip CAC2. The I/O chip IOC may be under the second peripheral circuit chip PC2. The third peripheral circuit chip PC3 may be disposed under the I/O chip IOC. The third cell array chip CAC3 may be under the third peripheral circuit chip PC3. The fourth peripheral circuit chip PC4 may be under the third cell array chip CAC3. The fourth cell array chip CAC4 may be under the fourth peripheral circuit chip PC4.

The first cell array chip CAC1 may be bonded to the first peripheral circuit chip PC1 through the metal patterns MP11 and MP12. The second cell array chip CAC2 may be bonded to the second peripheral circuit chip PC2 through the metal patterns MP21 and MP22. The third cell array chip CAC3 may be bonded to the third peripheral circuit chip PC3 through the metal patterns MP31 and MP32. The fourth cell array chip CAC4 may be bonded to the fourth peripheral circuit chip PC4 through the metal patterns MP41 and MP42.

The first peripheral circuit chip PC1 may be electrically connected to the I/O chip IOC through a first connection unit and a second connection unit. Each of the first connection unit and the second connection unit may include a TSV and pass through the first peripheral circuit chip PC1, the second cell array chip CAC2, and the second peripheral circuit chip PC2.

In an embodiment, the I/O chip IOC may further include a buffer chip. The buffer chip may be a chip configured to interface signals transmitted and received between the memory controller 100 and the first cell array chip CAC1, the second cell array chip CAC2, the third cell array chip CAC3, and the fourth cell array chip CAC4 to reduce load on the I/O chip IOC.

FIG. 22 is a view illustrating a memory device 200k according to embodiments. FIG. 22 may be described with reference to FIG. 21, and repeated descriptions may be omitted.

The description below focuses on differences between the memory device 200k of FIG. 22 and the memory device 200j of FIG. 21.

Referring to FIG. 22, the memory device 200k may include a first cell array chip CAC1, a first peripheral circuit chip PC1, a second cell array chip CAC2, a second peripheral circuit chip PC2, an I/O chip IOC, a third peripheral circuit chip PC3, a third cell array chip CAC3, a fourth peripheral circuit chip PC4, and a fourth cell array chip CAC4. Also, the memory device 200k may include a first bonding pad PD1, a second bonding pad PD2, metal patterns MP11, MP12, MP21, MP22, MP31, MP32, MP41, and MP42, contact plugs PT11, PT12, PT21, PT22, PT31, PT32, PT41, and PT42, contact bonding pads PBP11, PBP12, PBP21, PBP22, PBP31, PBP32, PBP41, and PBP42, TSVs TSV11, TSV12, TSV21, TSV22, TSV31, TSV32, TSV41, TSV42, TSV51, TSV52, TSV61, and TSV62, and TSV connection units BP11, BP12, BP21, BP22, BP31, BP32, BP41, BP42, BP51, BP52, BP61, and BP62.

The first peripheral circuit chip PC1 may transmit and receive data to and from the I/O chip IOC through the second peripheral circuit chip PC2. Components included in the first peripheral circuit chip PC1 may transmit and receive data to and from the second peripheral circuit chip PC2 through the TSVs TSV11, TSV12, TSV21, and TSV22.

The TSVs TSV11 and TSV12 may pass through the first peripheral circuit chip PC1. The TSVs TSV21 and TSV22 may pass through the first cell array chip CAC1. The TSVs TSV31, TSV32, TSV33, and TSV34 may pass through the second peripheral circuit chip PC2.

The TSVs TSV11 and TSV12 may be electrically connected to components of the first peripheral circuit chip PC1. The TSV TSV11 may be electrically connected to the TSV TSV21 through the TSV connection unit BP11. The TSV TSV12 may be electrically connected to the TSV TSV22 through the TSV connection unit BP12. The TSV TSV21 may be electrically connected to the second peripheral circuit chip PC2 through the TSV connection unit BP21. The TSV TSV22 may be electrically connected to the second peripheral circuit chip PC2 through the TSV connection unit BP22.

The TSV TSV31 and the TSV TSV32 may pass through the second peripheral circuit chip PC2. The TSVs TSV31 and TSV32 may be electrically connected to components of the second peripheral circuit chip PC2. The TSV TSV31 may be electrically connected to the I/O chip IOC through the TSV connection unit BP31. The TSV TSV32 may be electrically connected to the I/O chip IOC through the TSV connection unit BP32.

The TSV TSV41 and the TSV TSV42 may pass through the third peripheral circuit chip PC3. The TSVs TSV41 and TSV42 may be electrically connected to components of the third peripheral circuit chip PC3. The TSV TSV41 may be electrically connected to the I/O chip IOC through the TSV connection unit BP41. The TSV TSV42 may be electrically connected to the I/O chip IOC through the TSV connection unit BP42.

The fourth peripheral circuit chip PC4 may transmit and receive data to and from the I/O chip IOC through the third peripheral circuit chip PC3. Components included in the fourth peripheral circuit chip PC4 may transmit and receive data to and from the third peripheral circuit chip PC3 through the TSVs TSV51, TSV52, TSV61, and TSV62.

The TSVs TSV41 and TSV42 may pass through the third peripheral circuit chip PC3. The TSVs TSV51 and TSV52 may pass through the third cell array chip CAC3. The TSVs TSV61 and TSV62 may pass through the fourth peripheral circuit chip PC4.

The TSV TSV51 may be electrically connected to the third peripheral circuit chip PC3 through the TSV connection unit BP51. The TSV TSV52 may be electrically connected to the third peripheral circuit chip PC3 through the TSV connection unit BP52.

The TSV TSV51 may be electrically connected to the TSV TSV61 through the TSV connection unit BP61. The TSV TSV52 may be electrically connected to the TSV TSV62 through the TSV connection unit BP62. The TSVs TSV61 and TSV62 may be electrically connected to components of the fourth peripheral circuit chip PC4.

In an embodiment, the memory device 200k may not include the I/O chip IOC. In this case, the third peripheral circuit chip PC3 of the memory device 200k may have the same structure as the second peripheral circuit chip PC2_DB shown in FIGS. 17 to 20. That is, a page buffer circuit may be formed on a front surface of the third peripheral circuit chip PC3, and the first I/O circuit 301, the second I/O circuit 302, the first pad pad circuit 303, and the second pad circuit 304 may be formed on a rear surface of the third peripheral circuit chip PC3.

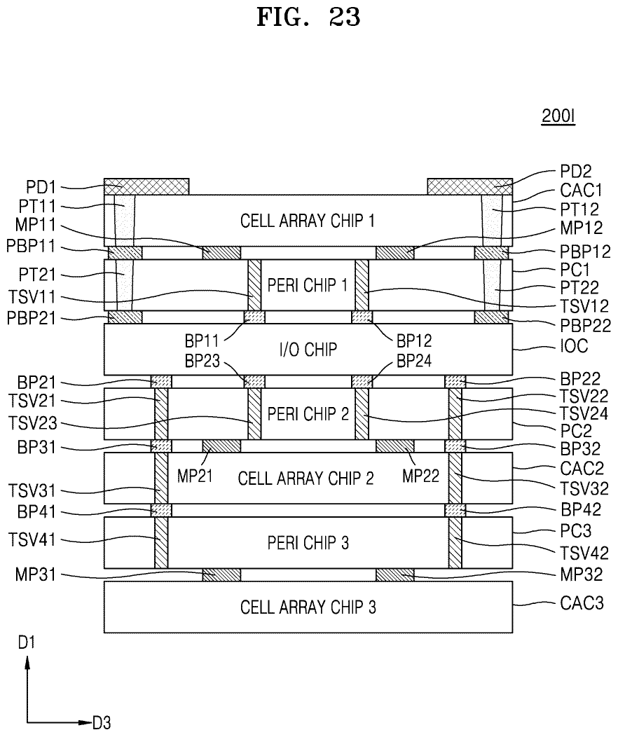

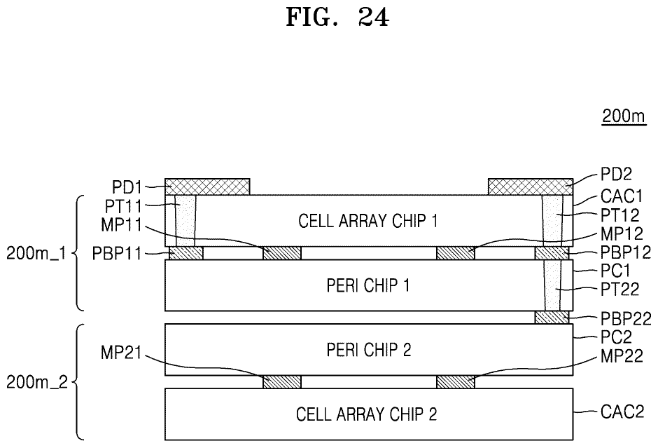

FIG. 23 is a view illustrating a memory device 2001 according to embodiments. FIG. 23 may be described with reference to FIG. 21, and repeated descriptions may be omitted.

The description below focuses on differences between the memory device 2001 of FIG. 23 and the memory device 200j of FIG. 21.

Referring to FIG. 23, the memory device 2001 may include a first cell array chip CAC1, a first peripheral circuit chip PC1, an I/O chip IOC, a second peripheral circuit chip PC2, a second cell array chip CAC2, a third peripheral circuit chip PC3, a third cell array chip CAC3, a first bonding pad PD1, a second bonding pad PD2, metal patterns MP11, MP12, MP21, MP22, MP31, and MP32, contact plugs PT11, PT12, PT21, and PT22, contact bonding pads PBP11, PBP12, PBP21, and PBP22, TSVs TSV11, TSV12, TSV21, TSV22, TSV23, TSV24, TSV31, TSV32, TSV41, and TSV42, and TSV connection units BP11, BP12, BP21, BP22, BP23, BP24, BP31, BP32, BP41, and BP42.

Chips included in the memory device 2001 may be asymmetrically arranged about the I/O chip IOC. Specifically, the first peripheral circuit chip PC1 may be under the first cell array chip CAC1. The I/O chip IOC may be under the first peripheral circuit chip PC1. The second peripheral circuit chip PC2 may be under the I/O chip IOC. The second cell array chip CAC2 may be under the second peripheral circuit chip PC2. The third peripheral circuit chip PC3 may be under the second cell array chip CAC2. The third cell array chip CAC3 may be under the third peripheral circuit chip PC3.

The first cell array chip CAC1 may be bonded to the first peripheral circuit chip PC1 through the metal patterns MP11 and MP12. The second cell array chip CAC2 may be bonded to the second peripheral circuit chip PC2 through the metal patterns MP21 and MP22. The third cell array chip CAC3 may be bonded to the third peripheral circuit chip PC3 through the metal patterns MP31 and MP32.

The contact plug PT11 and the contact plug PT12 may pass through the first cell array chip CAC1. The contact plug PT21 and the contact plug PT22 may pass through the first peripheral circuit chip PC1.

The first bonding pad PD1 may be electrically connected to the contact bonding pad PBP11 through the contact plug PT11. The second bonding pad PD2 may be electrically connected to the contact bonding pad PBP12 through the contact plug PT12. The contact plug PT11 may be electrically connected to the contact plug PT21 through the contact bonding pad PBP11. The contact plug PT12 may be electrically connected to the contact plug PT22 through the contact bonding pad PBP12. The contact plug PT21 may be electrically connected to the I/O chip IOC through the contact bonding pad PBP21. The contact plug PT22 may be electrically connected to the I/O chip IOC through the contact bonding pad PBP22.

The TSVs TSV11 and TSV12 may pass through the first peripheral circuit chip PC1. The TSVs TSV21, TSV22, TSV23, and TSV24 may pass through the second peripheral circuit chip PC2. The TSVs TSV31 and TSV32 may pass through the second cell array chip CAC2. The TSVs TSV41 and TSV42 may pass through the third peripheral circuit chip PC3.

The TSVs TSV11 and TSV12 may be electrically connected to components included in the first peripheral circuit chip PC1. The TSV TSV11 may be electrically connected to the I/O chip IOC through the TSV connection unit BP11. The TSV TSV12 may be electrically connected to the I/O chip IOC through the TSV connection unit BP12.

The TSV TSV21 may be electrically connected to the I/O chip IOC through the TSV connection unit BP21. The TSV TSV22 may be electrically connected to the I/O chip IOC through the TSV connection unit BP22. The TSV TSV23 may be electrically connected to the I/O chip IOC through the TSV connection unit BP23. The TSV TSV24 may be electrically connected to the I/O chip IOC through the TSV connection unit BP24.

The TSVs TSV23 and TSV24 may be electrically connected to components included in the second peripheral circuit chip PC2. The TSV TSV21 may be electrically connected to the TSV TSV31 through the TSV connection unit BP31. The TSV TSV22 may be electrically connected to the TSV TSV32 through the TSV connection unit BP32. The TSV TSV31 may be electrically connected to the TSV TSV41 through the TSV connection unit BP41. The TSV TSV32 may be electrically connected to the TSV TSV42 through the TSV connection unit BP42. The TSVs TSV41 and TSV42 may be electrically connected to components included in the third peripheral circuit chip PC3.

In an embodiment, the memory device 2001 may not include the I/O chip IOC. In this case, the second peripheral circuit chip PC2 of the memory device 2001 may have the same structure as the second peripheral circuit chip PC2_DB shown in FIGS. 17 to 20. That is, a page buffer circuit may be formed on a front surface of the second peripheral circuit chip PC2, and the first I/O circuit 301, the second I/O circuit 302, a first pad circuit 303, and a second pad circuit 304 may be formed on a rear surface of the second peripheral circuit chip PC2.

FIG. 24 is a view illustrating a memory device 200m according to embodiments.

Referring to FIG. 24, the memory device 200m may include a first cell array chip CAC1, a first peripheral circuit chip PC1, a second peripheral circuit chip PC2, a second cell array chip CAC2, a first bonding pad PD1, a second bonding pad PD2, metal patterns MP11, MP12, MP21, and MP22, contact plugs PT11, PT12, and PT22, and contact bonding pads PBP11, PBP12, and PBP22.

The first cell array chip CAC1 may be bonded to the first peripheral circuit chip PC1 through the metal patterns MP11 and MP12. The second cell array chip CAC2 may be bonded to the second peripheral circuit chip PC2 through the metal patterns MP21 and MP22.

The memory device 200m may be divided into a first memory device 200m_1 and a second memory device 200m_2. The first memory device 200m_1 may include the first cell array chip CAC1 and the first peripheral circuit chip PC1. The second memory device 200m_2 may include the second cell array chip CAC2 and a second peripheral circuit chip PC2.

The first peripheral circuit chip PC1 may include a page buffer circuit configured to write data to a memory cell array of the first cell array chip CAC1 or read data from the memory cell array of the first cell array chip CAC1. The first peripheral circuit chip PC1 may include an I/O circuit configured to perform an I/O operation related to the first cell array chip CAC1.

The second peripheral circuit chip PC2 may include a page buffer circuit configured to write data to a memory cell array of the second cell array chip CAC2 or read data from the memory cell array of the second cell array chip CAC2. The second peripheral circuit chip PC2 may include an I/O circuit configured to an I/O operation related to the second cell array chip CAC2.

The contact plugs PT11 and PT12 may pass through the first cell array chip CAC1. The contact plug PT22 may pass through the first peripheral circuit chip PC1.

The contact plug PT11 may electrically connect the first bonding pad PD1 to the contact bonding pad PBP11. The contact plug PT12 may electrically connect the second bonding pad PD2 to the contact bonding pad PBP12.

The contact bonding pad PBP11 may electrically connect the contact plug PT11 to the first peripheral circuit chip PC1. The contact bonding pad PBP12 may electrically connect the contact plug PT11 to the contact plug PT22. The contact plug PT22 may be electrically connected to the second peripheral circuit chip PC2 through the contact bonding pad PBP22.

The first memory device 200m_1 may transmit and receive data to and from a memory controller 100 through the first bonding pad PD1. The second memory device 200m_2 may transmit and receive data to and from the memory controller 100 through the second bonding pad PD2.

In an embodiment, the first memory device 200m_1 may write data to the memory cell array of the first cell array chip CAC1 or read data from the memory cell array of the first cell array chip CAC1 through the first bonding pad PD1.

In an embodiment, the second memory device 200m_2 may write data to the memory cell array of the second cell array chip CAC2 or read data from the memory cell array of the second ell array chip CAC2 through the second bonding pad PD2.

FIG. 25 is a view illustrating a memory device 1500 according to some embodiments of the present disclosure.

Referring to FIG. 25, the memory device 1500 may have a chip-to-chip (C2C) structure. At least one upper chip including a cell region and a lower chip including a peripheral circuit region PERI may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu—Cu bonding method. Alternatively, the bonding metal patterns may be formed of aluminum (Al) or tungsten (W).

The memory device 1500 may include the at least one upper chip including the cell region. For example, as illustrated in FIG. 25, the memory device 1500 may include two upper chips. However, the number of the upper chips is not limited thereto. In the case in which the memory device 1500 includes the two upper chips, a first upper chip including a first cell region CELL1, a second upper chip including a second cell region CELL2, and the lower chip including the peripheral circuit region PERI may be manufactured separately, and then, the first upper chip, the second upper chip and the lower chip may be connected to each other by the bonding method to manufacture the memory device 1500. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a-Z-axis direction in FIG. 25. However, embodiments of the present disclosure are not limited thereto. In certain embodiments, one of the first upper chip and the second upper chip may be turned over and then may be connected to a corresponding chip by the bonding method.

Each of the peripheral circuit region PERI and the first cell region CELL1 and the second cell region CELL2 of the memory device 1500 may include an external pad bonding region PA, a word line bonding region WLBA, and a bit line bonding region BLBA.

The peripheral circuit region PERI may include a first substrate 1210 and a plurality of circuit elements 1220a, 1220b and 1220c formed on the first substrate 1210. An interlayer insulating layer 1215 including one or more insulating layers may be provided on the plurality of circuit elements 1220a, 1220b and 1220c, and a plurality of metal lines electrically connected to the plurality of circuit elements 1220a, 1220b and 1220c may be provided in the interlayer insulating layer 1215. For example, the plurality of metal lines may include first metal lines 1230a, 1230b and 1230c connected to the plurality of circuit elements 1220a, 1220b and 1220c, and second metal lines 1240a, 1240b and 1240c formed on the first metal lines 1230a, 1230b and 1230c. The plurality of metal lines may be formed of at least one from among various conductive materials. For example, the first metal lines 1230a, 1230b and 1230c may be formed of tungsten having a relatively high electrical resistivity, and the second metal lines 1240a, 1240b and 1240c may be formed of copper having a relatively low electrical resistivity.

The first metal lines 1230a, 1230b and 1230c and the second metal lines 1240a, 1240b and 1240c are illustrated and described in the present embodiments. However, embodiments of the present disclosure are not limited thereto. In certain embodiments, at least one or more additional metal lines may further be formed on the second metal lines 1240a, 1240b and 1240c. In this case, the second metal lines 1240a, 1240b and 1240c may be formed of aluminum, and at least some of the additional metal lines formed on the second metal lines 1240a, 1240b and 1240c may be formed of copper having an electrical resistivity lower than an electrical resistivity of aluminum of the second metal lines 1240a, 1240b and 1240c.

The interlayer insulating layer 1215 may be disposed on the first substrate 1210 and may include an insulating material such as silicon oxide and/or silicon nitride.

Each of the first cell region CELL1 and the second cell region CELL2 may include at least one memory block. The first cell region CELL1 may include a second substrate 1310 and a common source line 1320. A plurality of word lines 1330 (e.g., word lines 1331 to 1338) may be stacked on the second substrate 1310 in a direction (i.e., the Z-axis direction) perpendicular to a top surface of the second substrate 1310. String selection lines and a ground selection line may be disposed on and under the word lines 1330, and the plurality of word lines 1330 may be disposed between the string selection lines and the ground selection line. Likewise, the second cell region CELL2 may include a third substrate 1410 and a common source line 1420, and a plurality of word lines 1430 (e.g., word lines 1431 to 1438) may be stacked on the third substrate 1410 in a direction (i.e., the Z-axis direction) perpendicular to a top surface of the third substrate 1410. Each of the second substrate 1310 and the third substrate 1410 may be formed of at least one from among various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first cell region CELL1 and the second cell region CELL2.

In some embodiments, as illustrated in a region Al corresponding to a region A, a channel structure CH may be provided in the bit line bonding region BLBA and may extend in the direction perpendicular to the top surface of the second substrate 1310 to penetrate the word lines 1330, the string selection lines, and the ground selection line. The channel structure CH may include a data storage layer, a channel layer, and a filling insulation layer. The channel layer may be electrically connected to a first metal line 1350c and a second metal line 1360c in the bit line bonding region BLBA. For example, the second metal line 1360c may be a bit line and may be connected to the channel structure CH through the first metal line 1350c. The second metal line 1360c (e.g., a bit line) may extend in a first direction (e.g., a Y-axis direction) parallel to the top surface of the second substrate 1310.

In some embodiments, as illustrated in a region A2 corresponding to a region A, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 1310 to penetrate the common source line 1320 and word lines 1331 and 1332 (e.g., lower word lines). The lower channel LCH may include a data storage layer, a channel layer, and a filling insulation layer and may be connected to the upper channel UCH. The upper channel UCH may penetrate word lines 1333 to 1338 (e.g., upper word lines). The upper channel UCH may include a data storage layer, a channel layer, and a filling insulation layer, and the channel layer of the upper channel UCH may be electrically connected to the first metal line 1350c and the second metal line 1360c. As a length of a channel increases, due to characteristics of manufacturing processes, it may be difficult to form a channel having a substantially uniform width. The memory device 1500 according to the present embodiments may include a channel having improved width uniformity due to the lower channel LCH and the upper channel UCH which are formed by the processes performed sequentially.

In the case in which the channel structure CH includes the lower channel LCH and the upper channel UCH as illustrated in the region A2, a word line located near to a boundary between the lower channel LCH and the upper channel UCH may be a dummy word line. For example, the word lines 1332 and 1333 adjacent to the boundary between the lower channel LCH and the upper channel UCH may be the dummy word lines. In this case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it is possible to reduce an influence of a non-uniform channel width between the lower and upper channels LCH and UCH on an operation of the memory device.

Meanwhile, the number of the word lines 1331 and 1332 (e.g., lower word lines) penetrated by the lower channel LCH is less than the number of the word lines 1333 to 1338 (e.g., upper word lines) penetrated by the upper channel UCH in the region A2. However, embodiments of the present disclosure are not limited thereto. In certain embodiments, the number of the lower word lines penetrated by the lower channel LCH may be equal to or more than the number of the upper word lines penetrated by the upper channel UCH. In addition, structural features and connection relation of the channel structure CH disposed in the second cell region CELL2 may be substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 25, the first through-electrode THV1 may penetrate the common source line 1320 and the plurality of word lines 1330. In certain embodiments, the first through-electrode THV1 may further penetrate the second substrate 1310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some embodiments, the first through-electrode THV1 and the second through-electrode THV2 may be electrically connected to each other through a first through-metal pattern 1372d and a second through-metal pattern 1472d. The first through-metal pattern 1372d may be formed at a bottom end of the first upper chip including the first cell region CELL1, and the second through-metal pattern 1472d may be formed at a top end of the second upper chip including the second cell region CELL2. The first through-electrode THV1 may be electrically connected to the first metal line 1350c and the second metal line 1360c. A lower via 1371d may be formed between the first through-electrode THV1 and the first through-metal pattern 1372d, and an upper via 1471d may be formed between the second through-electrode THV2 and the second through-metal pattern 1472d. The first through-metal pattern 1372d and the second through-metal pattern 1472d may be connected to each other by the bonding method.

In addition, in the bit line bonding region BLBA, an upper metal pattern 1252 may be formed in an uppermost metal layer of the peripheral circuit region PERI, and an upper metal pattern 1392 having the same shape as the upper metal pattern 1252 may be formed in an uppermost metal layer of the first cell region CELL1. The upper metal pattern 1392 of the first cell region CELL1 and the upper metal pattern 1252 of the peripheral circuit region PERI may be electrically connected to each other by the bonding method. In the bit line bonding region BLBA, the second metal line 1360c (e.g., a bit line) may be electrically connected to a page buffer included in the peripheral circuit region PERI. For example, some of the circuit elements 1220c of the peripheral circuit region PERI may constitute the page buffer, and the second metal line 1360c (e.g., a bit line) may be electrically connected to the circuit elements 1220c constituting the page buffer through an upper bonding metal pattern 1370c of the first cell region CELL1 and an upper bonding metal pattern 1270c of the peripheral circuit region PERI.

Referring continuously to FIG. 25, in the word line bonding region WLBA, the word lines 1330 of the first cell region CELL1 may extend in a second direction (e.g., an X-axis direction) parallel to the top surface of the second substrate 1310 and may be connected to a plurality of cell contact plugs 1340 (e.g., contact plugs 1341 to 1347). First metal lines 1350b and second metal lines 1360b may be sequentially connected onto the cell contact plugs 1340 connected to the word lines 1330. In the word line bonding region WLBA, the cell contact plugs 1340 may be connected to the peripheral circuit region PERI through upper bonding metal patterns 1370b of the first cell region CELL1 and upper bonding metal patterns 1270b of the peripheral circuit region PERI.

The cell contact plugs 1340 may be electrically connected to a row decoder included in the peripheral circuit region PERI. For example, some of the circuit elements 1220b of the peripheral circuit region PERI may constitute the row decoder, and the cell contact plugs 1340 may be electrically connected to the circuit elements 1220b constituting the row decoder through the upper bonding metal patterns 1370b of the first cell region CELL1 and the upper bonding metal patterns 1270b of the peripheral circuit region PERI. In some embodiments, an operating voltage of the circuit elements 1220b constituting the row decoder may be different from an operating voltage of the circuit elements 1220c constituting the page buffer. For example, the operating voltage of the circuit elements 1220c constituting the page buffer may be greater than the operating voltage of the circuit elements 1220b constituting the row decoder.

Likewise, in the word line bonding region WLBA, the word lines 1430 of the second cell region CELL2 may extend in the second direction (e.g., the X-axis direction) parallel to the top surface of the third substrate 1410 and may be connected to a plurality of cell contact plugs 1440 (e.g., contact plugs 1441 to 1447). The cell contact plugs 1440 may be connected to the peripheral circuit region PERI through an upper metal pattern of the second cell region CELL2 and lower and upper metal patterns and a cell contact plug 1348 of the first cell region CELL1.

In the word line bonding region WLBA, the upper bonding metal patterns 1370b may be formed in the first cell region CELL1, and the upper bonding metal patterns 1270b may be formed in the peripheral circuit region PERI. The upper bonding metal patterns 1370b of the first cell region CELL1 and the upper bonding metal patterns 1270b of the peripheral circuit region PERI may be electrically connected to each other by the bonding method. The upper bonding metal patterns 1370b and the upper bonding metal patterns 1270b may be formed of aluminum, copper, or tungsten.

In the external pad bonding region PA, a lower metal pattern 1371e may be formed in a lower portion of the first cell region CELL1, and an upper metal pattern 1472a may be formed in an upper portion of the second cell region CELL2. The lower metal pattern 1371e of the first cell region CELL1 and the upper metal pattern 1472a of the second cell region CELL2 may be connected to each other by the bonding method in the external pad bonding region PA. Likewise, an upper metal pattern 1372a may be formed in an upper portion of the first cell region CELL1, and an upper metal pattern 1272a may be formed in an upper portion of the peripheral circuit region PERI. The upper metal pattern 1372a of the first cell region CELL1 and the upper metal pattern 1272a of the peripheral circuit region PERI may be connected to each other by the bonding method.

Common source line contact plugs 1380 and 1480 may be disposed in the external pad bonding region PA. The common source line contact plugs 1380 and 1480 may be formed of a conductive material such as a metal, a metal compound, and/or doped polysilicon. The common source line contact plug 1380 of the first cell region CELL1 may be electrically connected to the common source line 1320, and the common source line contact plug 1480 of the second cell region CELL2 may be electrically connected to the common source line 1420. A first metal line 1350a and a second metal line 1360a may be sequentially stacked on the common source line contact plug 1380 of the first cell region CELL1, and a first metal line 1450a and a second metal line 1460a may be sequentially stacked on the common source line contact plug 1480 of the second cell region CELL2.

Input/output pads (e.g., a first input/output pad 1205, a second input/output pad 1405, and a third input/output pad 1406) may be disposed in the external pad bonding region PA. Referring to FIG. 25, a lower insulating layer 1201 may cover a bottom surface of the first substrate 1210, and a first input/output pad 1205 may be formed on the lower insulating layer 1201. The first input/output pad 1205 may be connected to at least one of a plurality of the circuit elements 1220a disposed in the peripheral circuit region PERI through a first input/output contact plug 1203 and may be separated from the first substrate 1210 by the lower insulating layer 1201. In addition, a side insulating layer may be disposed between the first input/output contact plug 1203 and the first substrate 1210 to electrically isolate the first input/output contact plug 1203 from the first substrate 1210.

An upper insulating layer 1401 covering a top surface of the third substrate 1410 may be formed on the third substrate 1410. A second input/output pad 1405 and/or a third input/output pad 1406 may be disposed on the upper insulating layer 1401. The second input/output pad 1405 may be connected to at least one of the plurality of circuit elements 1220a disposed in the peripheral circuit region PERI through second input/output contact plugs 1403 and 1303, and the third input/output pad 1406 may be connected to at least one of the plurality of circuit elements 1220a disposed in the peripheral circuit region PERI through third input/output contact plugs 1404 and 1304.

In some embodiments, the third substrate 1410 may not be disposed in a region in which the input/output contact plug is disposed. For example, as illustrated in a region B, the third input/output contact plug 1404 may be separated from the third substrate 1410 in a direction parallel to the top surface of the third substrate 1410 and may penetrate an interlayer insulating layer 1415 of the second cell region CELL2 so as to be connected to the third input/output pad 1406. In this case, the third input/output contact plug 1404 may be formed by at least one of various processes.

In some embodiments, as illustrated in a region B1 corresponding to the region B, the third input/output contact plug 1404 may extend in a third direction (e.g., the Z-axis direction), and a diameter of the third input/output contact plug 1404 may become progressively greater toward the upper insulating layer 1401. In other words, a diameter of the channel structure CH described in the region Al may become progressively less toward the upper insulating layer 1401, but the diameter of the third input/output contact plug 1404 may become progressively greater toward the upper insulating layer 1401. For example, the third input/output contact plug 1404 may be formed after the second cell region CELL2 and the first cell region CELL1 are bonded to each other by the bonding method.

In certain embodiments, as illustrated in a region B2 corresponding to the region B, the third input/output contact plug 1404 may extend in the third direction (e.g., the Z-axis direction), and a diameter of the third input/output contact plug 1404 may become progressively less toward the upper insulating layer 1401. In other words, like the channel structure CH, the diameter of the third input/output contact plug 1404 may become progressively less toward the upper insulating layer 1401. For example, the third input/output contact plug 1404 may be formed together with the cell contact plugs 1440 before the second cell region CELL2 and the first cell region CELL1 are bonded to each other.

In certain embodiments, the input/output contact plug may overlap with the third substrate 1410. For example, as illustrated in a region C, the second input/output contact plug 1403 may penetrate the interlayer insulating layer 1415 of the second cell region CELL2 in the third direction (e.g., the Z-axis direction) and may be electrically connected to the second input/output pad 1405 through the third substrate 1410. In this case, a connection structure of the second input/output contact plug 1403 and the second input/output pad 1405 may be realized by various methods.

In some embodiments, as illustrated in a region C1 corresponding to the region C, an opening 1408 may be formed to penetrate the third substrate 1410, and the second input/output contact plug 1403 may be connected directly to the second input/output pad 1405 through the opening 1408 formed in the third substrate 1410. In this case, as illustrated in the region C1, a diameter of the second input/output contact plug 1403 may become progressively greater toward the second input/output pad 1405. However, embodiments of the present disclosure are not limited thereto, and in certain embodiments, the diameter of the second input/output contact plug 1403 may become progressively less toward the second input/output pad 1405.

In certain embodiments, as illustrated in a region C2 corresponding to the region C, the opening 1408 penetrating the third substrate 1410 may be formed, and a contact 1407 may be formed in the opening 1408. An end of the contact 1407 may be connected to the second input/output pad 1405, and another end of the contact 1407 may be connected to the second input/output contact plug 1403. Thus, the second input/output contact plug 1403 may be electrically connected to the second input/output pad 1405 through the contact 1407 in the opening 1408. In this case, as illustrated in the region C2, a diameter of the contact 1407 may become progressively greater toward the second input/output pad 1405, and a diameter of the second input/output contact plug 1403 may become progressively less toward the second input/output pad 1405. For example, the second input/output contact plug 1403 may be formed together with the cell contact plugs 1440 before the second cell region CELL2 and the first cell region CELL1 are bonded to each other, and the contact 1407 may be formed after the second cell region CELL2 and the first cell region CELL1 are bonded to each other.

In certain embodiments illustrated in a region C3 corresponding to the region C, a stopper 1409 may further be formed on a bottom end of the opening 1408 of the third substrate 1410, as compared with the embodiments of the region C2. The stopper 1409 may be a metal line formed in the same layer as the common source line 1420. Alternatively, the stopper 1409 may be a metal line formed in the same layer as at least one of the word lines 1430. The second input/output contact plug 1403 may be electrically connected to the second input/output pad 1405 through the contact 1407 and the stopper 1409.

Like the second input/output contact plug 1403 and the third input/output contact plug 1404 of the second cell region CELL2, a diameter of each of the second input/output contact plug 1303 and the third input/output contact plug 1304 of the first cell region CELL1 may become progressively less toward the lower metal pattern 1371e or may become progressively greater toward the lower metal pattern 1371e.

Meanwhile, in some embodiments, a slit 1411 may be formed in the third substrate 1410. For example, the slit 1411 may be formed at a certain position of the external pad bonding region PA. For example, as illustrated in a region D, the slit 1411 may be located between the second input/output pad 1405 and the cell contact plugs 1440 when viewed in a plan view. Alternatively, the second input/output pad 1405 may be located between the slit 1411 and the cell contact plugs 1440 when viewed in a plan view.

In some embodiments, as illustrated in a region D1 corresponding to the region D, the slit 1411 may be formed to penetrate the third substrate 1410. For example, the slit 1411 may be used to prevent the third substrate 1410 from being finely cracked when the opening 1408 is formed. However, embodiments of the present disclosure are not limited thereto, and in certain embodiments, the slit 1411 may be formed to have a depth ranging from about 60% to about 70% of a thickness of the third substrate 1410.

In certain embodiments, as illustrated in a region D2 corresponding to the region D, a conductive material 1412 may be formed in the slit 1411. For example, the conductive material 1412 may be used to discharge a leakage current occurring in driving of the circuit elements in the external pad bonding region PA to the outside. In this case, the conductive material 1412 may be connected to an external ground line.

In certain embodiments, as illustrated in a region D3 corresponding to the region D, an insulating material 1413 may be formed in the slit 1411. For example, the insulating material 1413 may be used to electrically isolate the second input/output pad 1405 and the second input/output contact plug 1403 disposed in the external pad bonding region PA from the word line bonding region WLBA. Since the insulating material 1413 is formed in the slit 1411, it is possible to prevent a voltage provided through the second input/output pad 1405 from affecting a metal layer disposed on the third substrate 1410 in the word line bonding region WLBA.

Meanwhile, in certain embodiments, the first input/output pad 1205, the second input/output pad 1405, and the third input/output pad 1406 may be selectively formed. For example, the memory device 1500 may be realized to include only the first input/output pad 1205 disposed on the first substrate 1210, to include only the second input/output pad 1405 disposed on the third substrate 1410, or to include only the third input/output pad 1406 disposed on the upper insulating layer 1401.

In some embodiments, at least one from among the second substrate 1310 of the first cell region CELL1 and the third substrate 1410 of the second cell region CELL2 may be used as a sacrificial substrate and may be completely or partially removed before or after a bonding process. An additional layer may be stacked after the removal of the substrate. For example, the second substrate 1310 of the first cell region CELL1 may be removed before or after the bonding process of the peripheral circuit region PERI and the first cell region CELL1, and then, an insulating layer covering a top surface of the common source line 1320 or a conductive layer for connection may be formed. Likewise, the third substrate 1410 of the second cell region CELL2 may be removed before or after the bonding process of the first cell region CELL1 and the second cell region CELL2, and then, the upper insulating layer 1401 covering a top surface of the common source line 1420 or a conductive layer for connection may be formed.

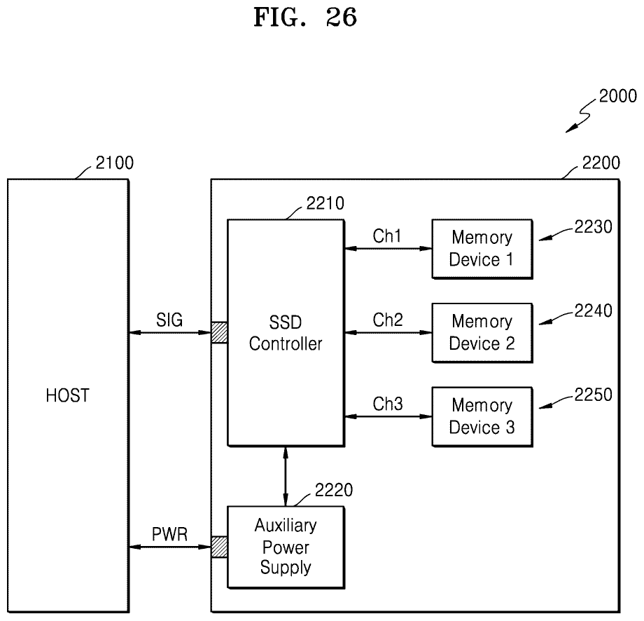

FIG. 26 is a block diagram of an example of applying a memory device according to embodiments to an SSD system 2000.

Referring to FIG. 26, the SSD system 2000 may include a host 2100 and an SSD 2200. The SSD 2200 may transmit and receive a signal to and from the host 2100 through a signal connector and receive power through a power connector. The SSD 2200 may include an SSD controller 2210, an auxiliary power supply 2220, a first memory device 2230, a second memory device 2240, and a third memory device 2250. Although the SSD 2200 is illustrated as including three memory devices as an example in FIG. 26, the SSD 2200 may include fewer or more memory devices than in FIG. 26.

Each of the first memory device 2230, the second memory device 2240, and the third memory device 2250 may be a vertical-stack-type NAND flash memory device. Each of the first memory device 2230, the second memory device 2240, and the third memory device 2250 may transmit and receive signals to the SSD controller 2210 through a first channel Ch1, a second channel Ch2, and a third channel Ch3. The first memory device 2230, the second memory device 2240, and the third memory device 2250 may be realized based on the embodiments described above with reference to FIGS. 1 to 25.

While non-limiting example embodiments of the present disclosure have been particularly shown and described with reference to the drawings, it will be understood that various changes in form and details may be made therein without departing from the spirit and scope of the present disclosure.

What is claimed is:

1. A memory device comprising:
a first cell array chip comprising a first memory cell array;
a first peripheral circuit chip comprising a first page buffer circuit electrically connected to the first memory cell array;
an input/output chip comprising a first pad circuit, a second pad circuit, a first input/output circuit electrically connected to the first pad circuit, and a second input/output circuit electrically connected to the second pad circuit;
a second cell array chip comprising a second memory cell array; and
a second peripheral circuit chip comprising a second page buffer circuit electrically connected to the second memory cell array.

2. The memory device of claim 1, further comprising:
a first bonding pad configured to electrically connect an external device to the memory device; and
a second bonding pad configured to electrically connect the external device to the memory device,
wherein the first peripheral circuit chip is under the first cell array chip,
wherein the input/output chip is under the first peripheral circuit chip,
wherein the second peripheral circuit chip is under the input/output chip,
wherein the second cell array chip is under the second peripheral circuit chip, and
wherein the first bonding pad and the second bonding pad are on the first cell array chip.

3. The memory device of claim 2, wherein the memory device further comprises:
first contact plugs passing through the first peripheral circuit chip and the first cell array chip, the first contact plugs configured to electrically connect the first pad circuit to the first bonding pad; and
second contact plugs passing through the first peripheral circuit chip and the first cell array chip, the second contact plugs configured to electrically connect the second pad circuit to the second bonding pad.

4. The memory device of claim 1, further comprising:
a first edge pad configured to electrically connect an external device to the memory device; and
a second edge pad configured to electrically connect the external device to the memory device,
wherein the first peripheral circuit chip is under the first cell array chip,
wherein the input/output chip is under the first peripheral circuit chip,
wherein the second peripheral circuit chip is under the input/output chip,
wherein the second cell array chip is under the second peripheral circuit chip, and
wherein the first edge pad and the second edge pad are between the first peripheral circuit chip and the second peripheral circuit chip.

5. The memory device of claim 2, wherein the memory device is configured to transmit and receive first data to and from the external device through the first bonding pad and the second bonding pad in response to a first command received from the external device.

6. The memory device of claim 2, wherein the memory device is configured to transmit and receive first data to and from the external device through the first bonding pad in response to a first command received from the external device, and transmit and receive second data to and from the external device through the second bonding pad in response to a second command received from the external device.

7. The memory device of claim 1, wherein the first memory cell array comprises a first memory region and a second memory region,
wherein the second memory cell array comprises a third memory region and a fourth memory region,
wherein the first page buffer circuit comprises a first page buffer overlapping with the first memory region in a vertical direction and a second page buffer overlapping with the second memory region in the vertical direction, and
wherein the second page buffer circuit comprises a third page buffer overlapping with the third memory region in the vertical direction and a fourth page buffer overlapping with the fourth memory region in the vertical direction.

8. The memory device of claim 7, wherein the memory device is configured to:
provide data stored in the first memory region to an external device through the first page buffer and the first input/output circuit;
provide data stored in the second memory region to the external device through the second page buffer and the first input/output circuit;
provide data stored in the third memory region to the external device through the third page buffer and the second input/output circuit; and
provide data stored in the fourth memory region to the external device through the fourth page buffer and the second input/output circuit.

9. The memory device of claim 7, wherein the memory device is configured to:
provide data stored in the first memory region to an external device through the first page buffer and the first input/output circuit;
provide data stored in the third memory region to the external device through the third page buffer and the first input/output circuit;
provide data stored in the second memory region to the external device through the second page buffer and the second input/output circuit; and
provide data stored in the fourth memory region to the external device through the fourth page buffer and the second input/output circuit.

10. The memory device of claim 9, wherein a distance between the first memory region and the first input/output circuit is less than a distance between the second memory region and the first input/output circuit, and
wherein a distance between the third memory region and the first input/output circuit is less than a distance between the fourth memory region and the first input/output circuit.

11. A memory device comprising:
a first cell array chip comprising a first memory cell array;
a first peripheral circuit chip comprising a first page buffer circuit electrically connected to the first memory cell array;
a second cell array chip comprising a second memory cell array; and
a second peripheral circuit chip comprising a second page buffer circuit, a first pad circuit, a second pad circuit, a first input/output circuit electrically connected to the first pad circuit, and a second input/output circuit electrically connected to the second pad circuit,
wherein the second page buffer circuit is electrically connected to the second memory cell array and formed on one surface of the second peripheral circuit chip, and
wherein the first pad circuit, the second pad circuit, the first input/output circuit, and the second input/output circuit are formed on another surface of the second peripheral circuit chip.

12. The memory device of claim 11, further comprising:
a first bonding pad configured to electrically connect an external device to the memory device; and
a second bonding pad configured to electrically connect the external device to the memory device,
wherein the first peripheral circuit chip is under the first cell array chip,
wherein the second peripheral circuit chip is under the first peripheral circuit chip,
wherein the second cell array chip is under the second peripheral circuit chip, and
wherein the first bonding pad and the second bonding pad are on the first cell array chip.

13. The memory device of claim 12, wherein the memory device further comprises:
a first contact passing through the first peripheral circuit chip and the first cell array chip, the first contact configured to electrically connect the first pad circuit to the first bonding pad; and
a second contact passing through the first peripheral circuit chip and the first cell array chip, the second contact configured to electrically connect the second pad circuit to the second bonding pad.

14. The memory device of claim 11, further comprising:
a first edge pad configured to electrically connect an external device to the memory device; and
a second edge pad configured to electrically connect the external device to the memory device,
wherein the first peripheral circuit chip is under the first cell array chip,
wherein the second peripheral circuit chip is under the first peripheral circuit chip,
wherein the second cell array chip is under the second peripheral circuit chip, and
wherein the first edge pad and the second edge pad are between the first peripheral circuit chip and the second peripheral circuit chip.

15. The memory device of claim 11, wherein the first memory cell array comprises a first memory region and a second memory region,
wherein the second memory cell array comprises a third memory region and a fourth memory region,
wherein the first page buffer circuit comprises a first page buffer overlapping with the first memory region in a vertical direction and a second page buffer overlapping with the second memory region in the vertical direction, and
wherein the second page buffer circuit comprises a third page buffer overlapping with the third memory region in the vertical direction and a fourth page buffer overlapping with the fourth memory region in the vertical direction.

16. The memory device of claim 15, wherein the memory device is configured to:
provide data stored in the first memory region to an external device through the first page buffer and the first input/output circuit;
provide data stored in the third memory region to the external device through the third page buffer and the first input/output circuit;
provide data stored in the second memory region to the external device through the second page buffer and the second input/output circuit; and
provide data stored in the fourth memory region to the external device through the fourth page buffer and the second input/output circuit.

17. The memory device of claim 16, wherein a distance between the first memory region and the first input/output circuit is less than a distance between the second memory region and the first input/output circuit, and
wherein a distance between the third memory region and the first input/output circuit is less than a distance between the fourth memory region and the first input/output circuit.

18. A memory device comprising:
a first cell array chip comprising a first memory cell array;
a first peripheral circuit chip comprising a first page buffer circuit electrically connected to the first memory cell array;
an input/output chip comprising a first pad circuit, a second pad circuit, a first input/output circuit electrically connected to the first pad circuit, and a second input/output circuit electrically connected to the second pad circuit;
a second cell array chip comprising a second memory cell array;
a second peripheral circuit chip comprising a second page buffer circuit electrically connected to the second memory cell array;
a third cell array chip comprising a third memory cell array; and
a third peripheral circuit chip comprising a third page buffer circuit electrically connected to the third memory cell array.

19. The memory device of claim 18, further comprising:
a first bonding pad configured to electrically connect an external device to the memory device; and
a second bonding pad configured to electrically connect the external device to the memory device,
wherein the first peripheral circuit chip is under the first cell array chip,
wherein the input/output chip is under the first peripheral circuit chip,
wherein the second peripheral circuit chip is under the input/output chip,
wherein the second cell array chip is under the second peripheral circuit chip,
wherein the third peripheral circuit chip is under the second cell array chip,
wherein the third cell array chip is under the third peripheral circuit chip,
wherein the first bonding pad and the second bonding pad are on the first cell array chip, and
wherein the third peripheral circuit chip is electrically connected to the input/output chip through at least one through-silicon via (TSV).

20. The memory device of claim 19, further comprising:
a first contact passing through the first peripheral circuit chip and the first cell array chip, the first contact configured to electrically connect the first pad circuit to the first bonding pad; and
a second contact passing through the first peripheral circuit chip and the first cell array chip, the second contact configured to electrically connect the second pad circuit to the second bonding pad.
